(19) United States
(12) Patent Application Publication
(10) Pub. No.: US 2026/0079312 A1
(43) Pub. Date: Mar. 19, 2026

(54) OPTICAL ENGINE DEVICE AND SEMICONDUCTOR PACKAGE INCLUDING THE SAME

(71) Applicant: SAMSUNG ELECTRONICS CO., LTD., Suwon-si (KR)

(72) Inventors: Jing Cheng LIN, Suwon-si (KR); Jung Hua CHANG, Suwon-si (KR)

(73) Assignee: SAMSUNG ELECTRONICS CO., LTD., Suwon-si (KR)

(21) Appl. No.: 19/226,777

(22) Filed: Jun. 3, 2025

(30) Foreign Application Priority Data
Sep. 19, 2024 (KR) 10-2024-0126789

(51) Int. Cl. G02B 6/42; H01L 25/16

(52) U.S. Cl. CPC G02B 6/4239; G02B 6/4245; H10W 90/00

(57) ABSTRACT

An optical engine device includes an integrated circuit chip having a top surface orthogonal to a vertical direction, a light-emitting device on the top surface of the integrated circuit chip and coupled with the integrated circuit chip, a first optical adhesive layer including a protrusion and configured to seal the light-emitting device, and an optical fiber plate including a cavity facing the first optical adhesive layer. The protrusion of the first optical adhesive layer is coupled with the optical fiber plate within the cavity.

### CROSS-REFERENCE TO RELATED APPLICATIONS

This application claims priority under 35 U.S.C. § 119 to Korean Patent Application No. 10-2024-0126789, filed on Sep. 19, 2024, in the Korean Intellectual Property Office, the disclosure of which is incorporated by reference herein in its entirety.

### BACKGROUND

### 1. Field

The present disclosure relates generally to semiconductor packages, and more particularly, to an optical engine device and a semiconductor package including the same.

### 2. Description of Related Art

A semiconductor package may refer to an integrated circuit chip implemented in a form suitable for use in electronic products. Typically, in a semiconductor package, semiconductor chips may be mounted on a printed circuit board and may be electrically connected to each other using bonding wires and/or bumps. Recent developments in an electronics industry may be directed towards research for potentially improving the performance of semiconductor packages.

### SUMMARY

One or more example embodiments of the present disclosure provide an optical engine device with improved reliability and a semiconductor package including the same, when compared to related semiconductor packages.

In addition, the technical goals to be achieved by the present disclosure are not limited to the technical goals mentioned above, and other technical goals may be clearly understood by one of ordinary skill in the art from the following descriptions.

According to an aspect of the present disclosure, an optical engine device includes an integrated circuit chip having a top surface orthogonal to a vertical direction, a light-emitting device on the top surface of the integrated circuit chip and coupled with the integrated circuit chip, a first optical adhesive layer including a protrusion and configured to seal the light-emitting device, and an optical fiber plate including a cavity facing the first optical adhesive layer. The protrusion of the first optical adhesive layer is coupled with the optical fiber plate within the cavity.

According to an aspect of the present disclosure, an optical engine device includes an integrated circuit chip including a first through via extending in a vertical direction, a photonics chip on the integrated circuit chip, a pair of chip bonding pads directly bonded to each other and disposed between the integrated circuit chip and the photonics chip, and a chip bonding insulation layer at least partially surrounding the pair of chip bonding pads and disposed between the integrated circuit chip and the photonics chip. The photonics chip includes a light-emitting device on the chip bonding insulation layer and coupled with the integrated circuit chip, a photo detector on the chip bonding insulation layer and laterally spaced apart from the light-emitting device, a wiring structure between the first through via and each of the pair of chip bonding pads, an optical adhesive layer including a protrusion and configured to seal the light-emitting device, and an optical fiber plate including a cavity facing the optical adhesive layer. The cavity of the optical fiber plate is at least partially filled by the protrusion of the optical adhesive layer.

According to an aspect of the present disclosure, a semiconductor package includes an interposer including an interposer substrate, a non-memory device on the interposer substrate, an optical engine device on the interposer substrate and laterally spaced apart from the non-memory device, and a sealing layer on the interposer substrate and configured to seal the non-memory device and the optical engine device. The optical engine device includes an integrated circuit chip including a through via extending in a vertical direction, a wiring structure on the integrated circuit chip and coupled with the integrated circuit chip, a light-emitting device on the wiring structure and coupled with the wiring structure, a photo detector on the wiring structure and laterally spaced apart from the light-emitting device, an optical adhesive layer including a protrusion and configured to seal the light-emitting device, and an optical fiber plate including a cavity facing the optical adhesive layer and at least partially surrounding the protrusion.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying diagrams, in which:

FIG. 1 is a cross-sectional view illustrating an optical engine device, according to an embodiment;

FIG. 2A is an enlarged cross-sectional view of a region CX of FIG. 1, according to an embodiment;

FIG. 2B is a plan view of the region CX shown in FIG. 1, according to an embodiment;

FIG. 2C is a plan view of an optical engine device corresponding to FIG. 2B, according to an embodiment;

FIGS. 2D, 2E, and 2F are enlarged cross-sectional views corresponding to FIG. 2A, of optical engine devices, according to some embodiments;

FIGS. 3, 4, and 5 are cross-sectional views illustrating optical engine devices, according to some embodiments;

FIG. 6 is a cross-sectional view illustrating a semiconductor package, according to an embodiment;

FIG. 7 is a cross-sectional view illustrating a semiconductor package, according to an embodiment;

FIG. 8A is a cross-sectional view illustrating a semiconductor package, according to an embodiment;

FIG. 8B is a cross-sectional view of the semiconductor package shown in FIG. 8A, according to an embodiment;

FIG. 9 is a cross-sectional view illustrating a semiconductor package, according to an embodiment;

FIGS. 10A to 10E are cross-sectional views sequentially illustrating a process of manufacturing a semiconductor package, according to an embodiment;

FIGS. 11A to 11E are cross-sectional views sequentially illustrating a process of manufacturing a semiconductor package, according to an embodiment;

FIGS. 12A to 12D are cross-sectional views sequentially illustrating a process of manufacturing a semiconductor package, according to an embodiment; and

FIGS. 13A to 13H are cross-sectional views sequentially illustrating a process of manufacturing a semiconductor package, according to an embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, however, these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. For example, the articles “a” and “an” are intended to include one or more items, and may be used interchangeably with “one or more.” As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, or the like may be replaced with terms, such as “first,” “second,” third” to be used to describe relative positions of elements. The terms “first,” “second,” third” may be used to describe various elements, however, the elements are not limited by the terms and a “first element” may be referred to as a “second element”. Alternatively or additionally, the terms “first”, “second”, “third”, or the like may be used to distinguish components from each other and do not limit the present disclosure. For example, the terms “first”, “second”, “third”, or the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

As used herein, each of the terms “SiN”, “SiO”, “TaN”, “TiN”, or the like may refer to a material made of elements included in each of the terms and is not a chemical formula representing a stoichiometric relationship.

Hereinafter, various embodiments of the present disclosure are described with reference to the accompanying drawings.

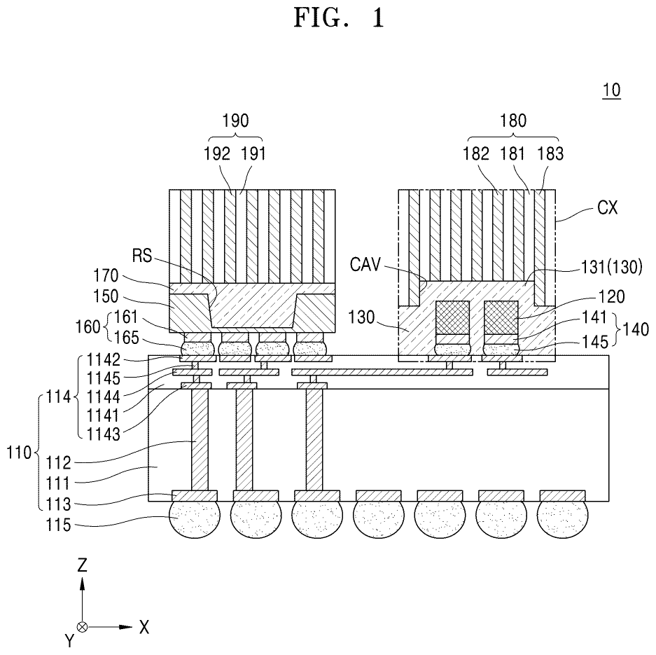

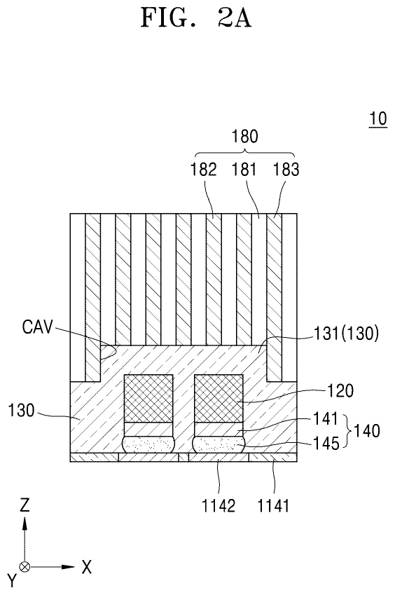

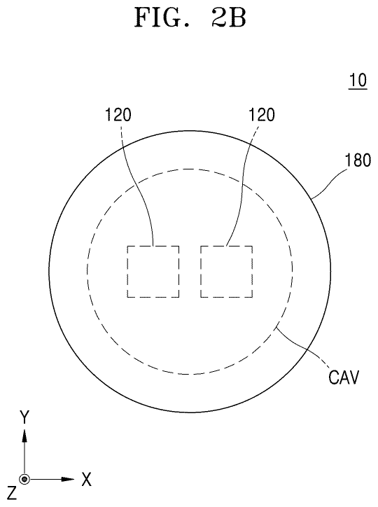

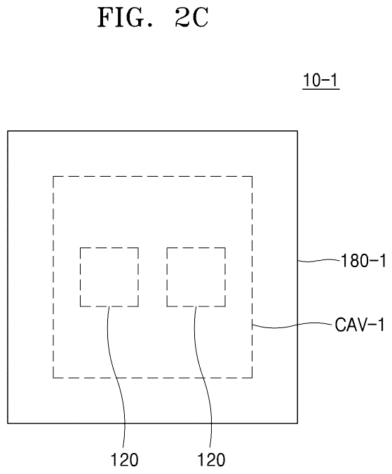

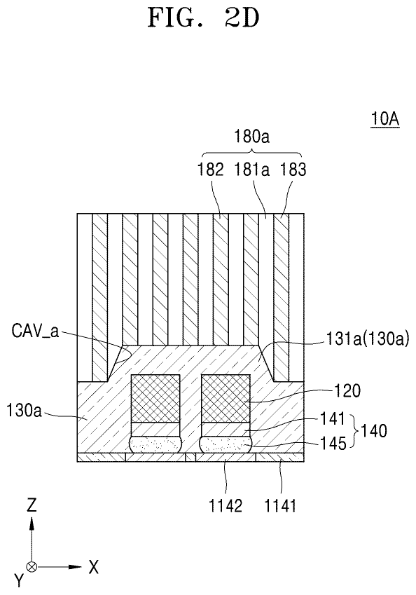

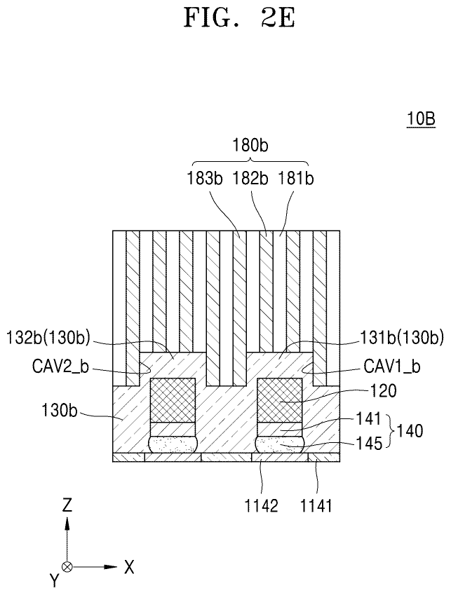

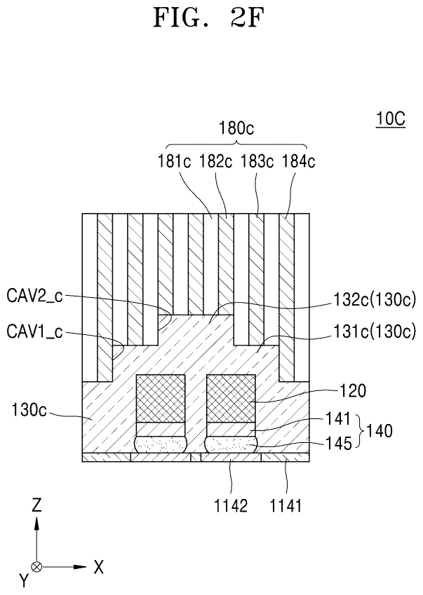

FIG. 1 is a cross-sectional view illustrating an optical engine device 10, according to an embodiment. FIG. 2A is an enlarged cross-sectional view of a region CX of FIG. 1, according to an embodiment. FIG. 2B is a plan view of the region CX shown in FIG. 1, according to an embodiment.

Referring to FIGS. 1, 2A, and 2B, the optical engine device 10 may include an integrated circuit chip 110, a connection terminal 115, a light-emitting device 120, a first optical adhesive layer 130, a first conductive bump 140, a photo detector 150, a second conductive bump 160, a second optical adhesive layer 170, a first optical fiber plate 180, and a second optical fiber plate 190.

The integrated circuit chip 110 may include a substrate 111, a through via 112, a conductive pad 113, and a wiring structure 114. The substrate 111 may provide a top surface orthogonal to a vertical direction (Z direction), and the top surface of the substrate 111 may be parallel to a first horizontal direction (X direction) and a second horizontal direction (Y direction). In an embodiment, a direction in which the photo detector 150 and the light-emitting device 120 are spaced from each other may be defined as the first horizontal direction (X direction), and a direction orthogonal to the first horizontal direction (X direction) and the vertical direction (Z direction) may be defined as the second horizontal direction (Y direction).

The substrate 111 may include a semiconductor material such as, but not limited to, silicon (Si) or germanium (Ge). In an embodiment, the integrated circuit chip 110 may include various microelectronic devices such as, but not limited to, a metal-oxide-semiconductor field effect transistor (MOSFET), a complementary metal-oxide-semiconductor (CMOS) transistor, a system large scale integration (LSI), a flash memory, a dynamic random access memory (DRAM), a static random access memory (SRAM), an electrically erasable programmable read-only memory (EEPROM), a parameter random access memory (PRAM), a magneto-resistive random access memory (MRAM), or a resistive random access memory (RERAM), an image sensor (e.g., a CMOS imaging sensor (CIS)), a micro-electro-mechanical system (MEMS), an active device, a passive device, or the like.

According to an embodiment, the through via 112 may penetrate through the substrate 111. For example, the through via 112 may penetrate through at least a portion of the substrate 111. The through via 112 may include a conductive material such as, but not limited to, copper (Cu), gold (Au), silver (Ag), nickel (Ni), tungsten (W), aluminum (Al), or a combination thereof. The through via 112 may provide an electrical connection path between electronic components within the substrate 111, the conductive pad 113, and the wiring structure 114.

According to an embodiment, a plurality of conductive pads 113 may be provided, and the plurality of conductive pads 113 may be arranged in the first horizontal direction (X direction) or the second horizontal direction (Y direction) along the bottom surface of the substrate 111. The top surface of the conductive pad 113 may be connected to contact the bottom surface of the through via 112. At least some of the plurality of conductive pads 113 may be connected to a plurality of through vias 112. In some embodiments, not all conductive pads of the plurality of conductive pads 113 may be connected to the plurality of through vias 112, and only some of the plurality of conductive pads 113 corresponding to the plurality of through vias 112 may be connected to the plurality of through vias 112.

The wiring structure 114 may be disposed on the top surface of the integrated circuit chip 110. The wiring structure 114 may extend along the top surface of the integrated circuit chip 110.

According to an embodiment, the wiring structure 114 may include an insulation layer 1141, an upper pad 1142, a lower pad 1143, a wiring pattern 1144, and a wiring via 1145.

The insulation layer 1141 may extend along the top surface of the integrated circuit chip 110, and the insulation layer 1141 may include an inorganic insulation layer such as, but not limited to, a silicon oxide (SiO) layer or a silicon nitride (SiN) layer. Alternatively or additionally, the insulation layer 1141 may include a polymer material. Alternatively or additionally, the insulation layer 1141 may include an insulation polymer or a photoimageable dielectric (PID). For example, the PID may include, but not be limited to, at least one of a photosensitive polyimide, a polybenzoxazole (PBO), a phenol-based polymer, or a benzocyclobutene-based polymer. The insulation layer 1141 may include two (2) or more insulation materials stacked on each other.

The upper pad 1142 may be disposed on the top surface of the insulation layer 1141, and the lower pad 1143 may be disposed on the bottom surface of the insulation layer 1141. A plurality of upper pads 1142 may be provided. For example, the plurality of upper pads 1142 may be exposed on the top surface of the insulation layer 1141, and some of the plurality of upper pads 1142 may provide terminals to which first solder patterns 145 of first conductive bumps 140 may be connected. Also, some other of the plurality of upper pads 1142 may provide terminals to which second solder patterns 165 of the second conductive bumps 160 may be connected.

The lower pad 1143 may be disposed on the bottom surface of the insulation layer 1141. The lower pad 1143 may be exposed on the bottom surface of the insulation layer 1141 and may provide a terminal to which the through via 112 may be connected.

The upper pad 1142 and the lower pad 1143 may each include a metal material such as, but not limited to, at least one of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or an alloy including two (2) or more metals.

A plurality of wiring patterns 1144 may be provided, and the plurality of wiring patterns 1144 may be arranged at different vertical levels within the insulation layer 1141. The wiring pattern 1144 may re-wire between the upper pad 1142 and the lower pad 1143. The wiring pattern 1144 may perform various functions depending on the design thereof. For example, the wiring pattern 1144 may include a ground pattern, a power pattern, a signal pattern, or the like. The signal pattern may include various signals (e.g., data signals) other than ground patterns, power patterns, or the like. As used herein, a pattern may include a wire and a pad.

The wiring pattern 1144 may include a conductive material such as, but not limited to, copper (Cu), gold (Au), silver (Ag), nickel (Ni), tungsten (W), aluminum (Al), or a combination thereof. According to some embodiments, the wiring pattern 1144 may further include a barrier material to prevent the conductive material from diffusing out of the wiring pattern 1144. The barrier material may include, but not be limited to, titanium (Ti), tantalum (Ta), titanium nitride (TiN), tantalum nitride (TaN), or a combination thereof.

The wiring via 1145 may electrically connect the plurality of wiring patterns 1144, the upper pads 1142, and lower pads 1143 at different vertical levels to one another, thereby forming an electrical path within the wiring structure 114. The wiring via 1145 may include a metal material such as, but not limited to, copper (Cu), aluminum (Al), silver (Ag), tin (Sn), gold (Au), nickel (Ni), lead (Pb), titanium (Ti), and an alloy thereof. The wiring via 1145 may be a filled type filled with a metal material and/or may be a conformal type in which the metal material is formed along the wall of a via hole. The wiring via 1145 may have a tapered cross-sectional shape. For example, the wiring via 1145 may have a tapered shape in which the width of the upper portion of a cross-section may be greater (wider) than the width of the lower portion of the cross-section.

According to some embodiments, the through via 112, the conductive pad 113, the upper pad 1142, the lower pad 1143, and the wiring via 1145 may further include a barrier material to potentially prevent conductive materials from diffusing out of the through via 112, the conductive pad 113, the upper pad 1142, the lower pad 1143, the wiring pattern 1144, the wiring via 1145, and the wiring via 1145. The barrier material may include, but not be limited to, titanium (Ti), tantalum (Ta), titanium nitride (TiN), tantalum nitride (TaN), or a combination thereof.

Connection terminals 115 may be arranged along the bottom surface of the substrate 111. The connection terminal 115 may be attached to the lower pad 1143 of the integrated circuit chip 110. The connection terminal 115 may serve as an external connection terminal of the integrated circuit chip 110. The connection terminal 115 may include a metal having a relatively low melting point (e.g., an alloy including tin (Sn)). The connection terminal 115 may include solder or the like. However, the present disclosure is not limited thereto.

The connection terminal 115 may be a land, a ball, a pin, or the like. The connection terminal 115 may be formed as a multiple layer or a single layer. When the connection terminal 115 is formed as a multiple layer, the connection terminal 115 may include a copper pillar and solder. When the connection terminal 115 is formed as a single layer, the connection terminal 115 may include tin (Sn), silver (Ag), solder, or copper (Cu). However, the present disclosure is not limited thereto. The number, spacing, arrangement, or the like of the connection terminals 115 may vary according to embodiments and/or design constraints.

According to an embodiment, the light-emitting device 120 may include a light-emitting diode (LED) or a vertical cavity surface-emitting laser (VCSEL), configured to emit an optical signal. However, examples of the light-emitting device 120 are not limited thereto, and any device configured to emit an optical signal may be included.

A plurality of light-emitting devices 120 may be provided, and the plurality of light-emitting devices 120 may be spaced apart from each other in a lateral direction (X direction and/or Y direction) on the wiring structure 114. According to an embodiment, the light-emitting device 120 may be mounted on the wiring structure 114 in a flip-chip bonding manner via the first conductive bump 140.

The light-emitting device 120 may be configured to convert an electrical signal received from the wiring structure 114 of the integrated circuit chip 110 into an optical signal. The optical signal converted by the light-emitting device 120 may be transmitted to the first optical fiber plate 180 through the first optical adhesive layer 130.

The first conductive bump 140 may be disposed at the bottom of the light-emitting device 120. The first conductive bump 140 may provide a connection path for an electrical signal between the light-emitting device 120 and the wiring structure 114 of the integrated circuit chip 110.

The first conductive bumps 140 may each include a first pillar pattern 141 and a first solder pattern 145. The first solder pattern 145 may include solder balls. The first solder pattern 145 may include a solder material. The solder material may include, but not be limited to, tin (Sn), bismuth (Bi), lead (Pb), silver (Ag), or an alloy thereof. The first pillar pattern 141 may be provided between the first solder pattern 145 and the upper pad 1142 corresponding to the first solder pattern 145 and may be electrically connected to the first solder pattern 145 and the upper pad 1142 corresponding to the first solder pattern 145. The first pillar pattern 141 may include a metal different from that included in the first solder pattern 145. For example, the first pillar pattern 141 may include, but not be limited to, copper (Cu) or a copper alloy. In an embodiment, each of the first conductive bumps 140 may not include the first pillar pattern 141. For example, the first solder pattern 145 may be disposed directly on the bottom surface of one of the light-emitting devices 120 corresponding to the first solder pattern 145.

According to an embodiment, the first optical adhesive layer 130 may seal the light-emitting device 120 and the first conductive bump 140. The first optical adhesive layer 130 may include a material that may be cured by light and/or heat.

According to an embodiment, sidewalls of the first optical adhesive layer 130 may be aligned with sidewalls of the first optical fiber plate 180. However, the present disclosure is not limited in this regard. For example, according to an embodiment, sidewalls of the first optical adhesive layer 130 may protrude in a lateral direction (X direction and/or Y direction) with respect to sidewalls of the first optical fiber plate 180.

The first optical adhesive layer 130 may fill the space between the plurality of light-emitting devices 120 and may be configured to completely seal the light-emitting devices 120 and the first conductive bumps 140 to not to be exposed to the outside.

The first optical adhesive layer 130 may include a protrusion 131 protruding in the vertical direction (Z direction). The protrusion 131 may be located near (e.g., in relatively close proximity) the center of the first optical adhesive layer 130 in a plan view. According to some embodiments, the protrusion 131 may have the shape of a circular pillar and/or a rectangular pillar.

The first optical adhesive layer 130 may include a light-transmitting material. Therefore, an optical signal emitted from the light-emitting device 120 may pass through the first optical adhesive layer 130 and reach the first optical fiber plate 180 disposed on the first optical adhesive layer 130.

For example, the first optical adhesive layer 130 may include, but not be limited to, silicon (Si) or epoxy resin.

According to an embodiment, the first optical fiber plate 180 may be disposed on the first optical adhesive layer 130. According to some embodiments, the first optical fiber plate 180 may be directly attached to the first optical adhesive layer 130.

The first optical fiber plate 180 may include a first protective layer 181, an inner optical fiber 182, and an outer optical fiber 183. The first protective layer 181 may serve to secure the inner optical fiber 182 and the outer optical fiber 183 and/or protect the inner optical fiber 182 and the outer optical fiber 183 from external impact. Outer sidewalls of the first protective layer 181 may form the outer shape of the first optical fiber plate 180. For example, the first protective layer 181 may include a translucent and/or transparent polymer material.

The inner optical fiber 182 and the outer optical fiber 183 may provide a path through which light emitted from the light-emitting device 120 may travel. The light may be and/or may include an optical signal and/or a laser beam.

According to an embodiment, the first optical fiber plate 180 may include a cavity CAV defined on the bottom surface of the first optical fiber plate 180 facing the light-emitting device 120. According to some embodiments, the shape of the cavity CAV may correspond to the shape of the protrusion 131 of the first optical adhesive layer 130. When the shape of the cavity CAV corresponds to the shape of the protrusion 131, the first optical fiber plate 180 and the first optical adhesive layer 130 may directly contact each other. When another material and/or another component is provided between the first optical fiber plate 180 and the first optical adhesive layer 130, the shape of the cavity CAV may not correspond to the shape of the protrusion 131.

The inner optical fiber 182 may refer to an optical fiber that may overlap the cavity CAV in the vertical direction (Z direction), and the outer optical fiber 183 may refer to an optical fiber that may not overlap the cavity CAV in the vertical direction (Z direction).

The bottom surface of the inner optical fiber 182 may be exposed within the cavity CAV, and, according to some embodiments, the side surface of the outer optical fiber 183 may be exposed within the cavity CAV.

According to an embodiment, the protrusion 131 of the first optical adhesive layer 130 may be surrounded by the first optical fiber plate 180 within the cavity CAV. Also, the cavity CAV of the first optical fiber plate 180 may be filled with the protrusion 131 of the first optical adhesive layer 130. When the cavity CAV of the first optical fiber plate 180 is filled with the protrusion 131, the protrusion 131 may be engaged with the first optical fiber plate 180 within the cavity CAV.

According to an embodiment, by inserting the protrusion 131 of the first optical adhesive layer 130 into the cavity CAV of the first optical fiber plate 180, the first optical fiber plate 180 may be stably bonded to the first optical adhesive layer 130 without tilting. Since the first optical fiber plate 180 is not tilted, the optical signal may move comparatively more stably between the light-emitting device 120 and the first optical fiber plate 180. Also, the top surface of the light-emitting device 120 and the first optical fiber plate 180 may not directly contact each other, and the first optical adhesive layer 130 may be provided between the light-emitting device 120 and the first optical fiber plate 180. Therefore, the first optical fiber plate 180 may be disposed without being damaged when the first optical fiber plate 180 is aligned on the light-emitting device 120.

As shown in FIG. 2B, the plurality of light-emitting devices 120 may completely overlap the cavity CAV of the first optical fiber plate 180 in the vertical direction (Z direction). That is, the plurality of light-emitting devices 120 may completely overlap the protrusion 131 of the first optical adhesive layer 130 in the vertical direction (Z direction).

According to an embodiment, the photo detector 150 may be provided on the wiring structure 114 of the integrated circuit chip 110. According to an embodiment, the photo detector 150 may be mounted on the wiring structure 114 in a flip-chip bonding manner via the second conductive bump 160.

The photo detector 150 may be configured to convert an optical signal introduced by the second optical fiber plate 190 into an electrical signal. The electrical signal converted by the photo detector 150 may be transmitted to the integrated circuit chip 110 through the wiring structure 114.

According to an embodiment, the photo detector 150 may be and/or may include a light-receiving device and may be configured to convert an optical signal into an electrical signal. The photo detector 150 may include, but not be limited to, a photo diode, a CMOS image sensor, a charge-coupled device (CCD), or a photo transistor. However, the photo detector 150 is not limited in this regard, and may include any semiconductor device configured to convert an optical signal into an electrical signal. The second conductive bump 160 may be disposed at the bottom of the photo detector 150. The second conductive bump 160 may provide a connection path for an electrical signal between the photo detector 150 and the wiring structure 114 of the integrated circuit chip 110.

A plurality of second conductive bumps 160 may be provided, and the plurality of second conductive bumps 160 may each include a second pillar pattern 161 and a second solder pattern 165. The second solder pattern 165 may include solder balls. The second pillar pattern 161 may be provided between the second solder pattern 165 and the upper pad 1142 corresponding to the second solder pattern 165 and may be electrically connected to the second solder pattern 165 and the upper pad 1142 corresponding to the second solder pattern 165. The second pillar pattern 161 may include a metal different from that included in the second solder pattern 165. In an embodiment, each of the second conductive bumps 160 may not include the second pillar pattern 161. For example, the second solder pattern 165 may be disposed directly on the bottom surface of the photo detector 150.

The material included in the second pillar pattern 161 may be substantially similar to and/or the same as the material included in the first pillar pattern 141, and the material included in the second solder pattern 165 may be substantially similar to and/or the same as the material included in the first solder pattern 145.

According to an embodiment, the photo detector 150 may include a recess RS recessed from the top surface of the photo detector 150 toward the integrated circuit chip 110. The second optical adhesive layer 170 may be provided on the second optical fiber plate 190 and the photo detector 150. The second optical adhesive layer 170 may extend along the top surface of the photo detector 150 to fill the recess RS.

When the recess RS is defined on the top surface of the photo detector 150, an optical signal entering the photo detector 150 may be guided by the recess RS. Therefore, when the recess RS is defined on the top surface of the photo detector 150, light loss due to movement in the photo detector 150 may be reduced, and thus the efficiency of the photo detector 150 may be improved, when compared to a related photo detector.

According to an embodiment, the second optical adhesive layer 170 may extend along the top surface of the photo detector 150 to fill the recess RS. Since the material included in the second optical adhesive layer 170 may be substantially similar to and/or the same as the material included in the first optical adhesive layer 130. Consequently, repeated descriptions thereof may be omitted for the sake of brevity.

According to an embodiment, the second optical fiber plate 190 may be disposed on the second optical adhesive layer 170. According to some embodiments, the second optical fiber plate 190 may be directly attached to the second optical adhesive layer 170.

The second optical fiber plate 190 may include a second protective layer 191 and an optical fiber 192. The second protective layer 191 may serve to fix the optical fiber 192 and protect the optical fiber 192 from external impact. Outer sidewalls of the second protective layer 191 may form the outer shape of the second optical fiber plate 190. For example, the second protective layer 191 may include a translucent and/or transparent polymer material.

The optical fiber 192 may provide a path through which light flowing from the outside to the photo detector 150 may travel. The light may be and/or may include an optical signal and/or a laser beam.

The bottom surface of the optical fiber 192 of the second optical fiber plate 190 may be in direct contact with the second optical adhesive layer 170.

FIG. 2C is a plan view of an optical engine device 10-1 corresponding to FIG. 2B, according to an embodiment. The optical engine device 10-1 may include and/or may be similar in many respects to the optical engine device 10 described above with reference to FIGS. 1 and 2B, and may include additional features not mentioned above. Consequently, repeated descriptions of the optical engine device 10-1 described above with reference to FIGS. 1 and 2B may be omitted for the sake of brevity.

Referring to FIG. 2C, a first optical fiber plate 180-1 may have a rectangular shape in a plan view. Also, a cavity CAV-1 formed in the first optical fiber plate 180-1 may also have a rectangular shape. The light-emitting device 120 may be positioned to overlap the cavity CAV-1.

Although FIGS. 2B and 2C illustrate the shapes of optical fiber plates and the shapes of cavities, the present disclosure is not limited to these exemplary shapes. That is, the shape of an optical fiber plate and/or the shape of a cavity may not be limited to a circular shape and/or a rectangular shape. For example, the shape of an optical fiber plate may be polygonal. Also, when the shape of an optical fiber plate is circular, the shape of a cavity may not necessarily be limited to a circular shape. Similarly, when the shape of an optical fiber unit is rectangular, the shape of a cavity may not necessarily be limited to a rectangular shape.

FIGS. 2D, 2E, and 2F are enlarged cross-sectional views of optical engine devices corresponding to FIG. 2A, according to some embodiments. The optical engine devices 10A, 10B, and 10C of FIGS. 2D, 2E, and 2F may respectively include and/or may be similar in many respects to the optical engine device 10 described above with reference to FIGS. 1 and 2A, and may include additional features not mentioned above. Consequently, repeated descriptions of the optical engine devices 10A, 10B, and 10C described above with reference to FIGS. 1 and 2A may be omitted for the sake of brevity.

Referring to FIG. 2D, a first optical fiber plate 180a of the optical engine device 10A may include a cavity CAV_a defined on the bottom surface of the first optical fiber plate 180 facing the light-emitting device 120. The sidewall of the cavity CAV_a shown in FIG. 2D may be inclined, unlike the cavity CAV shown in FIG. 2A.

Therefore, a protrusion 131a of a first optical adhesive layer 130a filling the cavity CAV_a may also have a tapered shape with an inclined sidewall.

The first optical fiber plate 180a may include a first protective layer 181a, the inner optical fiber 182, and the outer optical fiber 183. According to some embodiments, unlike the first protective layer 181 shown in FIG. 2A, a portion of the first protective layer 181a may be exposed within the cavity CAV_a.

Referring to FIG. 2E, a first optical fiber plate 180b of the optical engine device 10B may include a first cavity CAV1_b and a second cavity CAV2_b defined on the bottom surface of the first optical fiber plate 180b facing the light-emitting device 120. Unlike the first optical fiber plate 180 shown in FIG. 2A, the first optical fiber plate 180b shown in FIG. 2E may provide a plurality of cavities including the first cavity CAV1_b and the second cavity CAV2_b.

In this arrangement, light-emitting devices 120 may be arranged to overlap the plurality of cavities including the first cavity CAV1_b and the second cavity CAV2_b in the vertical direction (Z direction).

The bottom surface of an inner optical fiber 182b may be exposed within the first cavity CAV1_b and the second cavity CAV2_b, and, according to some embodiments, the side surface of an outer optical fiber 183b may be exposed within the first cavity CAV1_b and the second cavity CAV2_b. Unlike the first optical fiber plate 180 shown in FIG. 2A, a cavity may not be formed at the exact center of the first optical fiber plate 180b, and thus the outer optical fiber 183b may be disposed at the exact center of the first optical fiber plate 180b. The outer optical fiber 183b may refer to an optical fiber that may not overlap the first cavity CAV1_b and the second cavity CAV2_b, and the inner optical fiber 182b may refer to an optical fiber that may overlap the first cavity CAV1_b and the second cavity CAV2_b.

Also, a portion of a first protective layer 181b may be exposed within the first cavity CAV1_b and the second cavity CAV2_b.

A first optical adhesive layer 130b may include a first protrusion 131b and a second protrusion 132b respectively corresponding to the shapes of the first cavity CAV1_b and the second cavity CAV2_b. The first protrusion 131b and the second protrusion 132B may be spaced apart from each other in the first horizontal direction (X direction), the first protrusion 131b may fill the first cavity CAV1_b, and the second protrusion 132B may fill the second cavity CAV2_b.

Referring to FIG. 2F, a first optical fiber plate 180c of the optical engine device 10C may include a first cavity CAV1_c and a second cavity CAV2_c defined on the bottom surface of the first optical fiber plate 180c facing the light-emitting device 120. Unlike the first optical fiber plate 180 shown in FIG. 2A, the first optical fiber plate 180c shown in FIG. 2F may provide a plurality of cavities including the first cavity CAV1_c and the second cavity CAV2_c. Also, the first cavity CAV1_c and the second cavity CAV2_c shown in FIG. 2F may overlap in the vertical direction (Z direction) without being spaced apart from each other in the lateral direction (X direction and/or Y direction), unlike the first cavity CAV1_b and the second cavity CAV2_b shown in FIG. 2E.

The first cavity CAV1_c is a cavity defined on the bottom surface of the first optical fiber plate 180c and may be a cavity formed to completely overlap all of the plurality of light-emitting devices 120 in the vertical direction (Z direction). Also, the second cavity CAV2_c may be a cavity defined within the first cavity CAV1_c and formed to overlap at least some of the plurality of light-emitting devices 120 in the vertical direction (Z direction). The width of the second cavity CAV2_c in the lateral direction (X direction and/or Y direction) may be smaller (narrower) than the width of the first cavity CAV1_c in the lateral direction (X direction and/or Y direction).

According to an embodiment, the second cavity CAV2_c may be positioned at the exact center within the first cavity CAV1_c in a plan view. However, according to some embodiments, the second cavity CAV2_c may be positioned apart from the exact center within the first cavity CAV1_c.

The first optical fiber plate 180c may include a first protective layer 181c, a first inner optical fiber 182c, a second inner optical fiber 183c, and an outer optical fiber 184c. The first inner optical fiber 182c may be and/or may include an optical fiber positioned to overlap both the first cavity CAV1_c and the second cavity CAV2_c in the vertical direction (Z direction). The second inner optical fiber 183c may be and/or may include an optical fiber positioned to overlap the first cavity CAV1_c in the vertical direction (Z direction) and to not to overlap the second cavity CAV2_c in the vertical direction (Z direction).

A first optical adhesive layer 130c may include a first protrusion 131c corresponding to the shape of the first cavity CAV1_c and a second protrusion 132c corresponding to the shape of the second cavity CAV2_c. The first protrusion 131c and the second protrusion 132c may overlap each other in the vertical direction (Z direction), the first protrusion 131c may fill the first cavity CAV1_c, and the second protrusion 132c may fill the second cavity CAV2_c.

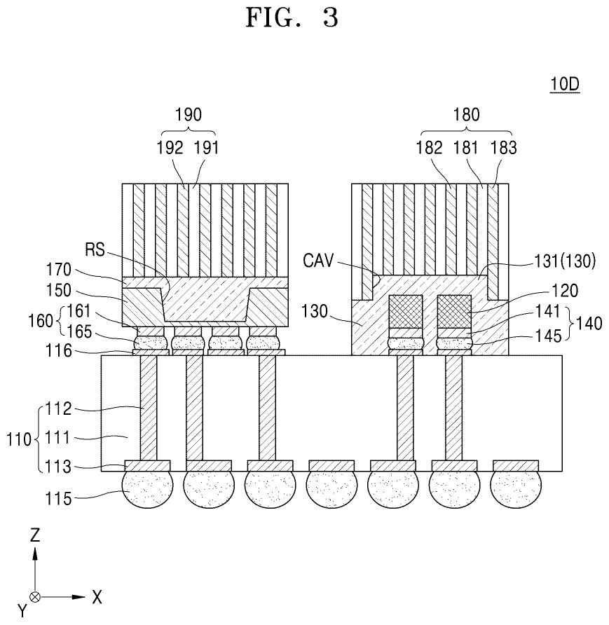

FIGS. 3, 4, and 5 are cross-sectional views illustrating optical engine devices 10D, 10E, and 10F, according to an embodiment.

An optical engine device 10D shown in FIG. 3 may be substantially similar to and/or the same as the optical engine device 10 shown in FIG. 1. However, the optical engine device 10D may not include the wiring structure 114. Consequently, repeated descriptions of the optical engine device 10D described above with reference to FIG. 1 may be omitted for the sake of brevity.

Referring to FIG. 3, a plurality of connection pads 116 may be arranged on the top surface of the substrate 111 of the integrated circuit chip 110. The plurality of connection pads 116 may be arranged along the top surface of the substrate 111. The through via 112 may be attached to the bottom surface of a connection pad 116. Also, the top surface of the connection pad 116 may be attached to the first solder pattern 145 of the first conductive bump 140 and the second solder pattern 165 of the second conductive bump 160.

In an embodiment, at least some of the plurality of through vias 112 may be arranged to overlap the photo detector 150 in the vertical direction (Z direction). Furthermore, other through vias 112 may be arranged to overlap the light-emitting device 120 in the vertical direction (Z direction).

Referring to the optical engine device 10 shown in FIG. 1, the plurality of through vias 112 may overlap only the photo detector 150 in the vertical direction (Z direction) and may not overlap the light-emitting device 120 in the vertical direction (Z direction). The photo detector 150 and the light-emitting device 120 may be electrically connected to the through via 112 through the wiring structure 114.

Alternatively, referring to the optical engine device 10D shown in FIG. 3, the wiring structure 114 may not be disposed on the substrate 111, and the second conductive bump 160 disposed under the photo detector 150 may be connected to the connection pad 116. In addition, the first conductive bump 140 disposed under the light-emitting device 120 may be connected to the connection pad 116.

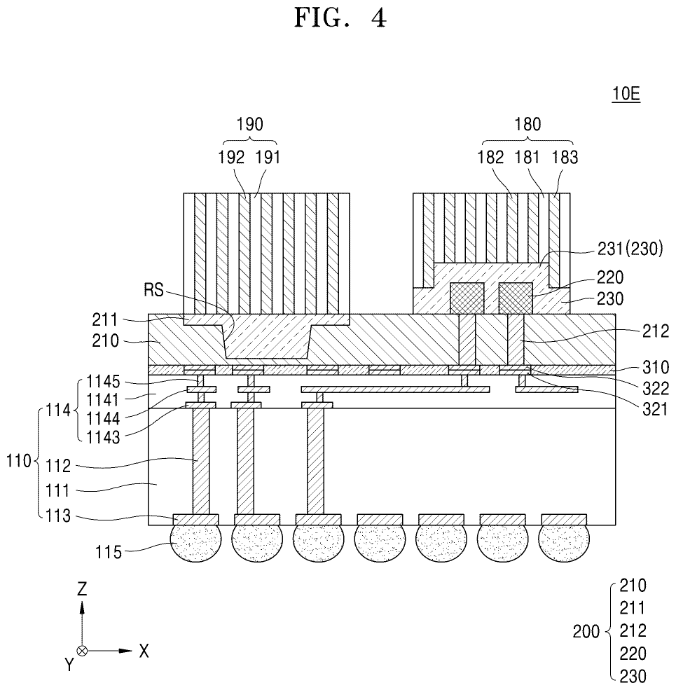

FIG. 4 is a cross-sectional view illustrating an optical engine device, according to an embodiment. The optical engine device 10E of FIG. 4 may include and/or may be similar in many respects to the optical engine device 10 described above with reference to FIG. 1, and may include additional features not mentioned above. For example, in the optical engine device 10E, a light-emitting device 220 and a photo detector 210 may be mounted on the integrated circuit chip 110 using a die-to-die bonding method, rather than a flip-chip bonding method. Consequently, repeated descriptions of the optical engine device 10E described above with reference to FIG. 1 may be omitted for the sake of brevity.

Referring to FIG. 4, the optical engine device 10D may include a chip bonding insulation layer 310, a lower chip bonding pad 321, and an upper chip bonding pad 322. The chip bonding insulation layer 310, the lower chip bonding pad 321, and the upper chip bonding pad 322 may be arranged on the top surface of the wiring structure 114.

According to an embodiment, the lower chip bonding pad 321 may be connected to the wiring via 1145 on the top surface of the insulation layer 1141. Also, the upper chip bonding pad 322 may be bonded to the lower chip bonding pad 321.

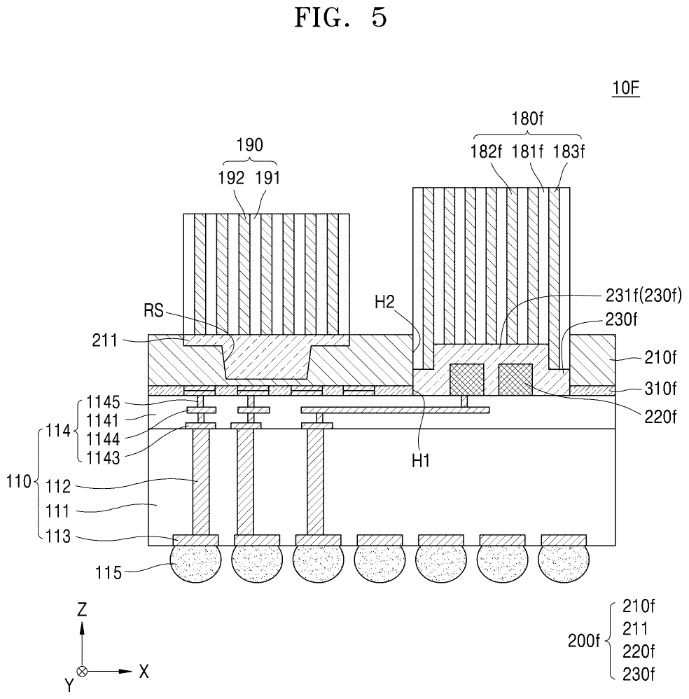

The bonding may include hybrid bonding. Hereinafter, for simplicity of description, a single lower chip bonding pad 321 and a single upper chip bonding pad 322 are described. During the direct bonding process, a metal within the lower chip bonding pad 321 may diffuse into the upper chip bonding pad 322, and a metal within the lower chip bonding pad 321 may diffuse into the upper chip bonding pad 322. Therefore, the upper chip bonding pad 322 may be firmly bonded to the lower chip bonding pad 321. The interface between the lower chip bonding pad 321 and the upper chip bonding pad 322 may be indistinguishable. The interface between the lower chip bonding pad 321 and the upper chip bonding pad 322 in FIGS. 4 and 5 may be and/or may include a virtual interface. The lower chip bonding pad 321 may include the same metal as the upper chip bonding pad 322. In an embodiment, the sidewall of the lower chip bonding pad 321 may not be vertically aligned with the sidewall of the upper chip bonding pad 322.

The chip bonding insulation layer 310 may be provided between the wiring structure 114 and the photo detector 210. The chip bonding insulation layer 310 may cover sidewalls of the lower chip bonding pad 321 and the upper chip bonding pad 322. The chip bonding insulation layer 310 may include a silicon-containing insulation material.

The chip bonding insulation layer 310 may be an insulation layer formed by chemically bonding two (2) insulation layers. The chemical bond may be a covalent bond. In an embodiment, the two (2) insulation layers may contain the same insulation material. The interface between the two (2) chemically bonded insulation layers may be indistinguishable. Therefore, there may be no distinct interface within the chip bonding insulation layer 310.

The integrated circuit chip 110 and an optical device chip 200 may be attached to each other through die-to-die bonding (e.g., hybrid bonding) between the lower chip bonding pad 321 and the upper chip bonding pad 322.

The optical device chip 200 may include the photo detector 210, a first optical adhesive layer 230, a second optical adhesive layer 211, a second through via 212, and the light-emitting device 220.

According to an embodiment, the photo detector 210 may be disposed on the chip bonding insulation layer 310. Unlike the photo detector 150 shown in FIG. 1, the photo detector 210 shown in FIG. 4 may be positioned to cover the substrate 111 of the integrated circuit chip 110 in a plan view. That is, the sidewalls of the photo detector 210 and the sidewalls of the integrated circuit chip 110 may be aligned with each other.

According to an embodiment, the second through via 212 may extend from the bottom surface of the photo detector 210 to the top surface of the photo detector 210 through the photo detector 210.

The second through via 212 may be connected to the upper chip bonding pad 322 and the light-emitting device 220 to provide an electrical connection path between the upper chip bonding pad 322 and the light-emitting device 220. That is, an electrical signal of the integrated circuit chip 110 may be provided to the light-emitting device 220 through the second through via 212, and the light-emitting device 220 may convert the electrical signal into an optical signal and provide the optical signal to the first optical fiber plate 180.

According to an embodiment, the length of the second through via 212 in the vertical direction (Z direction) may be substantially similar to and/or the same as (equal to) the length of the photo detector 210 in the vertical direction (Z direction).

Compared to the photo detector 150 shown in FIG. 1, the photo detector 210 shown in FIG. 4 may have a different shape, however, the photo detector 210 may perform with a substantially similar and/or a same function of converting an optical signal provided from the second optical fiber plate 190 into an electrical signal.

According to an embodiment, the photo detector 210 shown in FIG. 4 may include the recess RS recessed in the vertical direction Z direction on the top surface, similar to the photo detector 150 shown in FIG. 1. The recess RS may be filled with the second optical adhesive layer 211.

According to an embodiment, a plurality of light-emitting devices 220 may be provided on the top surface of the photo detector 210. The plurality of light-emitting devices 220 may overlap and be connected respectively corresponding second through vias 212.

The second optical fiber plate 190 may be attached to the second optical adhesive layer 211 buried in the recess RS of the photo detector 210. The bottom surface of the second optical fiber plate 190 may be in direct contact with the top surface of the second optical adhesive layer 211. According to an embodiment, when no other material is provided between an optical fiber and an optical adhesive layer and the optical fiber and the optical adhesive layer are in direct contact with each other, an optical signal passing through the optical fiber may be transmitted to the optical adhesive layer more efficiently without measureable optical loss. Similarly, when an optical signal is transmitted from the optical adhesive layer to the optical fiber, the optical signal passing through the optical fiber may also be transmitted to the optical adhesive layer without measureable optical loss.

FIG. 5 is a cross-sectional view illustrating an optical engine device, according to an embodiment. The optical engine device 10F of FIG. 5 may include and/or may be similar in many respects to the optical engine device 10 described above with reference to FIG. 1, and may include additional features not mentioned above. For example, in the optical engine device 10F, a light-emitting device 220f may not be mounted on a photo detector 210f. Rather, the light-emitting device 220f may be disposed within a hole (e.g., a second hole H2) formed in the photo detector 210f and may be directly connected to the wiring structure 114. Consequently, repeated descriptions of the optical engine device 10F described above with reference to FIG. 4 may be omitted for the sake of brevity.

Referring to FIG. 5 below, a chip bonding insulation layer 310f and the photo detector 210f may include holes, that is, a first hole H1 and a second hole H2, penetrating through the chip bonding insulation layer 310 and the photo detector 210f in the vertical direction (Z direction). In an embodiment, the first hole H1 of the chip bonding insulation layer 310f may be completely aligned with the second hole H2 of the photo detector 210f in the vertical direction (Z direction).

The light-emitting device 220f may be disposed in the first hole H1 of the chip bonding insulation layer 310f and the second hole H2 of the photo detector 210f. According to an embodiment, the light-emitting device 220f may be directly connected to the wiring structure 114. That is, the light-emitting device 220f may be directly connected to the wiring via 1145 of the wiring structure 114 and may be electrically connected to the integrated circuit chip 110.

A first optical adhesive layer 230f including a protrusion 231f may also be configured to be positioned within the first hole H1 and the second hole H2 to seal the light-emitting device 220f. That is, the bottom surface of a first optical adhesive layer 230f may be in contact with the insulation layer 1141 of the wiring structure 114, and the side surfaces of the first optical adhesive layer 230f may be in contact with the chip bonding insulation layer 310f and the photo detector 210f. The shape of the first optical adhesive layer 230f may be substantially similar to and/or the same as the shape of the first optical adhesive layer 130 shown in FIG. 2. Consequently, repeated descriptions of the first optical adhesive layer 230f with reference to FIG. 2 may be omitted below for the sake of brevity.

A portion of a first optical fiber plate 180f directly connected to the first optical adhesive layer 230f may be disposed within the second hole H2. The side surfaces of the first optical fiber plate 180f may partially contact the photo detector 210f.

The sidewalls of the first protective layer 181f of the first optical fiber plate 180f may also contact the inner wall of the second hole H2 of the photo detector 210f. Also, an inner optical fiber 182f and an outer optical fiber 183f of the first optical fiber plate 180f may be positioned within the second hole H2 of the photo detector 210f.

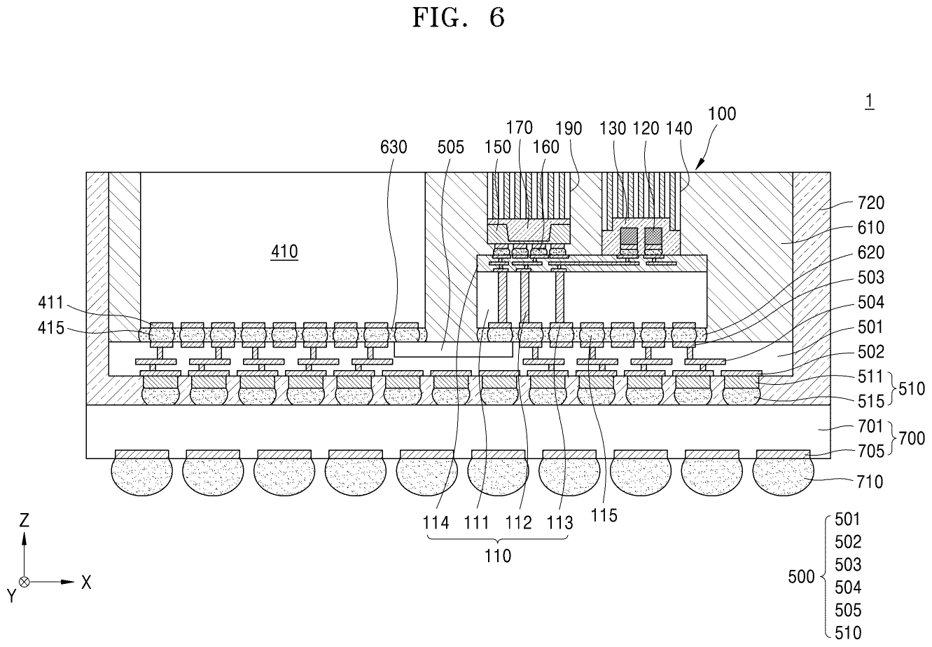

FIG. 6 is a cross-sectional view illustrating a semiconductor package 1, according to an embodiment.

The semiconductor package 1 shown in FIG. 6 may include and/or may be similar in many respects the optical engine device 10 described above with reference in FIGS. 1, 2A, and 2B, and may include additional features not mentioned above. Consequently, repeated descriptions of the semiconductor package 1 described above with reference to FIGS. 1, 2A, and 2B may be omitted for the sake of brevity.

Referring to FIG. 6, the semiconductor package 1 may include a semiconductor chip 410, a first chip pad 411, a chip bump 415, an interposer 500, an interposer bump 510, a first molding layer 610, a first underfill film 620, a second underfill film 630, a package substrate 700, an external connection terminal 710, and a second molding layer 720.

The package substrate 700 may include a base substrate 701 and a metal pad 705. According to an embodiment, upper metal pads may be provided on the top surface of the base substrate 701. The upper metal pads provided on the top surface of the base substrate 701 may be attached and electrically connected to interposer solder patterns 515 of interposer bumps 510.

The base substrate 701 may provide a top surface on which the interposer 500 is mounted.

According to an embodiment, metal wires may be provided within the base substrate 701 and electrically connected to the upper metal pads. Being electrically connected to the package substrate 700 may refer to being electrically connected to the metal wires. Metal pads 705 may be provided on the bottom surface of the base substrate 701. The metal pads 705 may be electrically connected to the upper metal pads through the metal wires.

According to an embodiment, the upper metal pads, the metal wires, and the metal pads 705 may include a conductive material, which may include, but not be limited to, copper (Cu), gold (Au), silver (Ag), nickel (Ni), tungsten (W), aluminum (Al), or a combination thereof.

Also, the base substrate 701 may include a semiconductor material such as, but not limited to, silicon (Si) or germanium (Ge).

External connection terminals 710 may be arranged on the bottom surface of the base substrate 701. For example, the external connection terminals 710 may be arranged on the bottom surfaces of the metal pads 705. The external connection terminals 710 may be electrically connected to the metal wires of the package substrate 700 through the metal pads 705. The external connection terminals 710 may include a solder material. The solder material may include, but not be limited to, tin (Sn), silver (Ag), zinc (Zn), and/or alloys thereof.

According to an embodiment, the interposer 500 may be provided on the top surface of the package substrate 700. The interposer 500 may include an interposer substrate 501, a lower substrate pad 502, an upper substrate pad 503, substrate wires 504, and a bridge structure 505.

The interposer substrate 501 may provide the top surface on which a semiconductor chip 410 and an optical engine device 100 may be mounted. Upper substrate pads 503 may be provided on the top surface of the interposer substrate 501. The substrate wires 504 are provided within the interposer substrate 501 and may be electrically connected to the upper substrate pads 503. Being electrically connected to the interposer substrate 501 may refer to being electrically connected to the substrate wires 504. Lower substrate pads 502 may be provided on the bottom surface of the interposer substrate 501. The lower substrate pads 502 may be electrically connected to the upper substrate pads 503 through the substrate wires 504.

Interposer bumps 510 may be provided between the package substrate 700 and the interposer substrate 501. For example, the interposer bumps 510 may be provided between the lower substrate pads 502 and the upper metal pads of the package substrate 700 to access the lower substrate pads 502 and the upper metal pads 705 of the package substrate 700.

The interposer bumps 510 may include an interposer pillar pattern 511 and an interposer solder pattern 515. The solder balls may include a solder material. The interposer solder pattern 515 may include solder balls. The interposer solder pattern 515 may include a solder material. The solder material may include, but not be limited to, tin (Sn), bismuth (Bi), lead (Pb), silver (Ag), or an alloy thereof. The interposer pillar pattern 511 may be provided between the lower substrate pad 502 and the interposer solder pattern 515, and the interposer pillar pattern 511 may be electrically connected to the interposer solder pattern 515 and the corresponding lower substrate pad 502. The interposer pillar pattern 511 may include a metal different from the material included in the interposer solder pattern 515. For example, the interposer pillar pattern 511 may include, but not be limited to, copper (Cu) or a copper alloy. In an embodiment, each of the interposer bumps 510 may not include the interposer pillar pattern 511. For example, the interposer solder pattern 515 may be disposed directly on the bottom surface of one of the lower substrate pads 502 corresponding to the interposer solder pattern 515.

According to an embodiment, the pitch of interposer pillar patterns 511 may be smaller than the pitch of the external connection terminals 710 of the package substrate 700.

According to an embodiment, the bridge structure 505 may be disposed within the interposer substrate 501. The bridge structure 505 may be disposed within the interposer substrate 501 to electrically connect the optical engine device 100 and the semiconductor chip 410. According to an embodiment, the bridge structure 505 may be and/or may include a silicon (Si) bridge embedded within the interposer substrate 501. The bridge structure 505 may be physically and electrically connected to a first chip bump 415 connected to the semiconductor chip 410 and the connection terminal 115 of the optical engine device 100, within the interposer substrate 501. Therefore, the semiconductor chip 410 and the optical engine device 100 may transmit and/or receive electrical signals to and/or from each other through the bridge structure 505 of the interposer 500.

According to an embodiment, the first underfill film 620 may be provided between the integrated circuit chip 110 of the optical engine device 100 and the interposer 500 to cover sidewalls of the connection terminal 115. The first underfill film 620 may include, but not be limited to, an insulation polymer.

According to an embodiment, the second underfill film 630 may be provided between the semiconductor chip 410 and the interposer 500 to cover the sidewalls of the first chip bump 415. The second underfill film 630 may include an insulation polymer.

The optical engine device 100 may be disposed on the top surface of the interposer 500. The optical engine device 100 may be spaced laterally apart from the semiconductor chip 410. The optical engine device 100 may be substantially similar to and/or the same as the optical engine device 10 described above with reference to FIG. 1. For example, the optical engine device 10 of FIG. 1 may be mounted on the interposer substrate 501 to form the optical engine device 100. Alternatively, an optical engine device 10A of FIG. 2D, an optical engine device 10B of FIG. 2E, an optical engine device 10C of FIG. 2F, an optical engine device 10D of FIG. 3, an optical engine device 10E of FIG. 4, or an optical engine device 10F of FIG. 5 may be mounted on the interposer substrate 501 to form the optical engine device 100. The optical engine device 100 may include the integrated circuit chip 110, the wiring structure 114, the light-emitting device 220f, the photo detector 150, the first conductive bump 140, the second conductive bump 160, the connection terminal 115, the first optical fiber plate 180, and the second optical fiber plate 190. The connection terminals 115 may be connected to corresponding upper substrate pads 503, respectively. Therefore, the optical engine device 100 may be electrically connected to the interposer 500 through the connection terminals 115. The optical engine device 100 and the semiconductor chip 410 may be electrically connected to each other through the interposer 500.

According to an embodiment, the first molding layer 610 may be provided on the top surface of the interposer 500 to cover the sidewalls of the semiconductor chip 410 and the sidewalls of the optical engine device 100. The first molding layer 610 may expose the top surface of the semiconductor chip 410 and at least a portion of the top surface of the optical engine device 100. The top surface of the optical engine device 100 may include the top surface of the first optical fiber plate 180 and the top surface of the second optical fiber plate 190. The sidewalls of the first molding layer 610 may be aligned with the sidewalls of the interposer substrate 501. The first molding layer 610 may include, but not be limited to, an insulation polymer such as, but not limited to, an epoxy-based molding compound (EMC).

According to an embodiment, the second molding layer 720 may be provided on the top surface of the package substrate 700 to cover the sidewalls of the first molding layer 610 and the sidewalls of the interposer substrate 501. The second molding layer 720 may expose the top surface of the semiconductor chip 410, the top surface of the first molding layer 610, and at least a portion of the top surface of the optical engine device 100. The top surface of the optical engine device 100 may include the top surface of the first optical fiber plate 180 and the top surface of the second optical fiber plate 190. The sidewalls of the second molding layer 720 may be aligned with the sidewalls of the base substrate 701. The second molding layer 720 may include, for example, an insulation polymer such as, but not limited to, an epoxy-based molding compound (EMC).

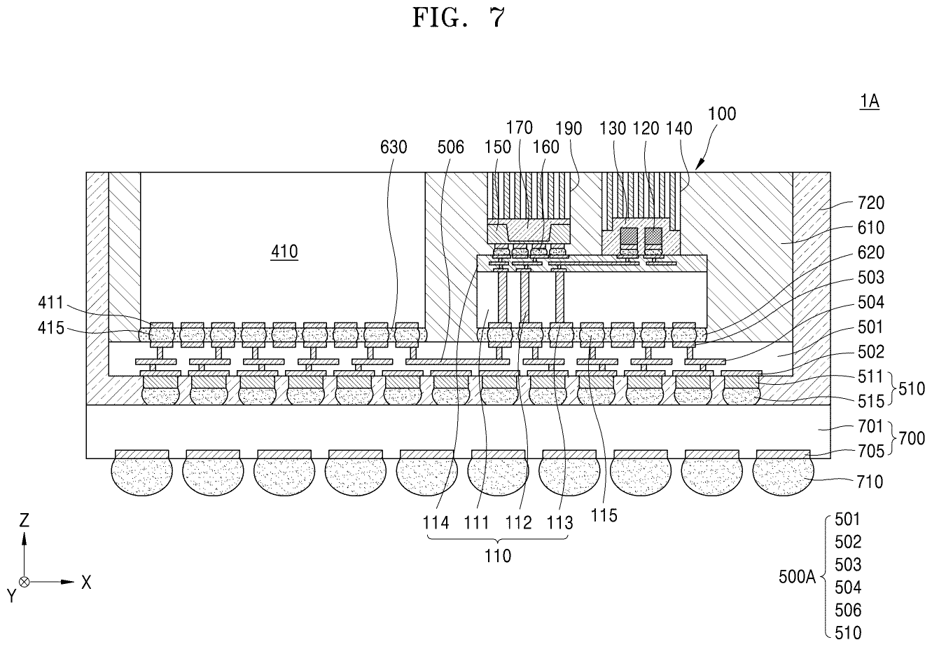

FIG. 7 is a cross-sectional view illustrating a semiconductor package, according to an embodiment.

A semiconductor package 1A shown in FIG. 7 may include and/or may be similar in many respects to the semiconductor package 1 shown in FIG. 6, and may include additional features not mentioned above. For example, the semiconductor package 1A may include a connection pattern 506 instead of the bridge structure 505. Consequently, repeated descriptions of the semiconductor package 1A described above with reference to FIG. 6 may be omitted for the sake of brevity.

Referring to FIG. 7, the interposer 500 of the semiconductor package 1A may include the connection pattern 506 instead of the bridge structure 505. The connection pattern 506 may have a structure similar to that of the substrate wires 504 of the interposer 500. Also, the connection pattern 506 may include the same conductive material as the substrate wires 504.

According to an embodiment, the connection pattern 506 may be disposed within the interposer substrate 501. The connection pattern 506 may be disposed within the interposer substrate 501 to electrically connect the optical engine device 100 and the semiconductor chip 410. According to an embodiment, the connection pattern 506 may be a conductive pattern buried in the interposer substrate 501. The connection pattern 506 may be physically and electrically connected to a first chip bump 415 connected to the semiconductor chip 410 and the connection terminal 115 of the optical engine device 100, within the interposer substrate 501. Therefore, the semiconductor chip 410 and the optical engine device 100 may transmit and/or receive electrical signals to and/or from each other through the connection pattern 506 of the interposer 500.

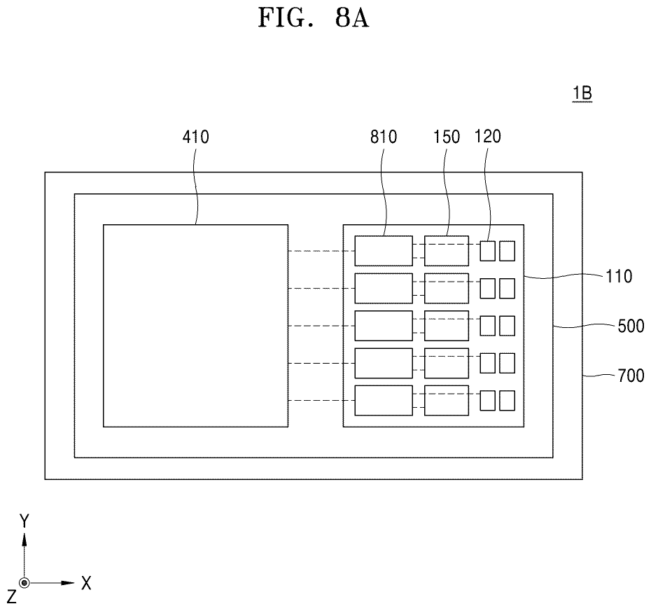

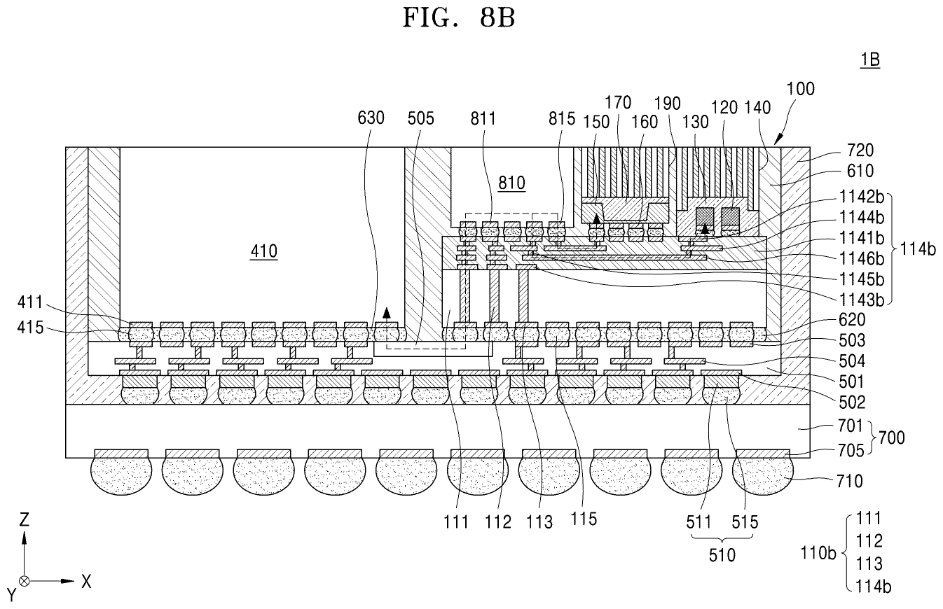

FIG. 8A is a cross-sectional view illustrating a semiconductor package 1B, according to an embodiment. FIG. 8B is a cross-sectional view of the semiconductor package 1B shown in FIG. 8A, according to an embodiment.

The semiconductor package 1B shown in FIGS. 8A and 8B may include and/or may be similar in many respects to the semiconductor package 1 shown in FIG. 6, and may include additional features not mentioned above. For example, a universal chiplet interconnect express (UCIE) chip 810 may be further mounted on the integrated circuit chip 110. Consequently, repeated descriptions of the semiconductor package 1B described above with reference to FIG. 6 may be omitted for the sake of brevity.

Referring to FIGS. 8A and 8B, the UCIE chip 810 may be mounted on the top surface of a wiring structure 114b of the integrated circuit chip 110. According to an embodiment, the UCIE chip 810 may be disposed on one side of the top surface of the wiring structure 114b in a plan view.

According to an embodiment, the UCIE chip 810 may be disposed on the wiring structure 114b and may be electrically connected to the integrated circuit chip 110 through the wiring structure 114b. The wiring structure 114b may include an insulation layer 1141b that covers conductive materials, upper pads 1142B spaced apart from each other along the top surface of the insulation layer 1141b, lower pads 1143b spaced apart from each other along the bottom surface of the insulation layer 1141b, a first wiring pattern 1144b buried in the insulation layer 1141b, a second wiring pattern 1146b, and a wiring via 1145b connected between a plurality of wiring patterns at different vertical levels. The insulation layer 1141b, the lower pads 1143b, the upper pads 1142B, and the wiring via 1145b may be substantially similar to and/or the same as the insulation layer 1141b, the lower pads 1143b, the upper pads 1142B, and the wiring via 1145b shown in FIG. 1, and thus repeated descriptions thereof may be omitted for the sake of brevity. In addition, the first wiring pattern 1144b may be substantially similar to and/or the same as the wiring pattern 1144 shown in FIG. 1, and as such, repeated descriptions thereof may be omitted for the sake of brevity.

According to an embodiment, the second wiring pattern 1146b of the wiring structure 114b may be and/or may include a conductive wiring pattern that provides an electrical connection path between the UCIE chip 810 and the light-emitting device 120. An electrical signal transmitted from the integrated circuit chip 110 may reach the UCIE chip 810 through the wiring structure 114b. Thereafter, the electrical signal transmitted to the UCIE chip 810 may be transmitted to the light-emitting device 120 through the second wiring pattern 1146b.

Also, the first wiring pattern 1144b of the wiring structure 114b may be and/or may include a conductive wiring pattern that may provide an electrical connection path between the UCIE chip 810 and the photo detector 150. An electrical signal transmitted from the integrated circuit chip 110 may reach the UCIE chip 810 through the wiring structure 114b. Thereafter, the electrical signal transmitted to the UCIE chip 810 may be transmitted to the photo detector 150 through the first wiring pattern 1144b.

The UCIE chip 810 may implement standardization of high-speed data transmission specifications between the semiconductor chip 410, the integrated circuit chip 110, the photo detector 150, and the light-emitting device 120, which may be independently manufactured. The UCIE chip 810 may enable implementation of high bandwidth by providing a path for electrical signals between the semiconductor chip 410, the integrated circuit chip 110, the photo detector 150, and the light-emitting device 120.

As shown in FIG. 8A, the semiconductor chip 410 may be electrically connected to the UCIE chip 810, and the UCIE chip 810 may be electrically connected to the photo detector 150 and the light-emitting device 120.

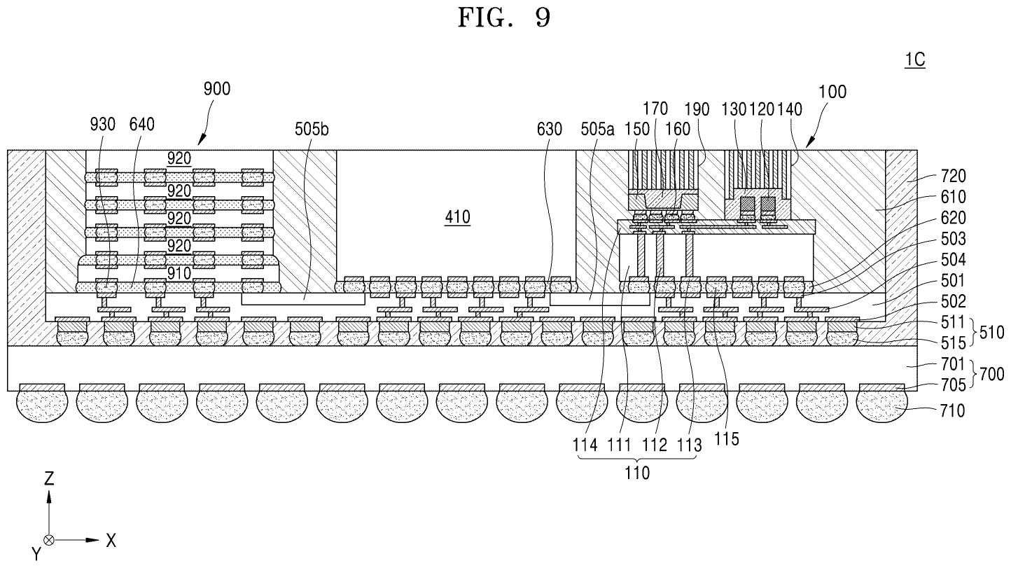

FIG. 9 is a cross-sectional view illustrating a semiconductor package 1C, according to an embodiment.

The semiconductor package 1C shown in FIG. 9 may include and/or may be similar in many respects to the semiconductor package 1 shown in FIG. 6 and may include additional features not mentioned above. For example, the semiconductor package 1C may further includes a memory device 900 mounted on the interposer 500. Consequently, repeated descriptions of the semiconductor package 1C described above with reference to FIG. 6 may be omitted for the sake of brevity.

Referring to FIG. 9, the semiconductor package 1C may include the memory device 900 mounted on the interposer 500. The memory device 900 may be disposed on the top surface of the interposer substrate 501 and may be spaced apart from the semiconductor chip 410 in the lateral direction (X direction and/or Y direction). The memory device 900 may be and/or may include a memory package. The memory device 900 may include a lower semiconductor chip 410 and upper semiconductor chips 920. The lower semiconductor chip 410 may correspond to the lowest semiconductor chip from among a plurality of semiconductor chips (e.g., a first semiconductor chip 910 and a second semiconductor chip 920) included in the memory device 900. For example, the lower semiconductor chip 410 may be and/or may include a logic buffer chip. The upper semiconductor chips 920 may be and/or may include a different type of semiconductor chip from the lower semiconductor chip 410 and the semiconductor chip 410. The upper semiconductor chips 920 may be and/or may include memory chips. The upper semiconductor chips 920 may include, but not be limited to, high bandwidth memory (HBM). For example, the upper semiconductor chips 920 may each include a DRAM. However, the present disclosure is not limited in this regard.

The semiconductor package 1C may include third conductive bumps 930 and a third underfill film 640. The third conductive bumps 930 may be provided between the memory device 900 and the interposer substrate 501 and may be connected to lower pads of the lower semiconductor chip 410 and the upper substrate pads 503 corresponding to the lower pads of the lower semiconductor chip 410. The memory device 900 may be electrically connected to the interposer substrate 501 through the third conductive bumps 930. Therefore, the memory device 900 and the semiconductor chip 410 may be electrically connected to each other through the interposer 500.

The third conductive bumps 930 may include solder balls. The solder balls may include a solder material. According to some embodiments, the third conductive bumps 930 may further include third conductive pillars. For example, the third conductive pillars may be provided between the memory device 900 and the solder balls and may include copper (Cu). The pitch of the third conductive bumps 930 may be smaller than the pitch of the interposer bumps 510. The third underfill film 640 may be provided between the lower semiconductor chip 410 and the interposer substrate 501 to cover the sidewalls of the third conductive bumps 930. The third underfill film 640 may include an insulation polymer.

According to an embodiment, the semiconductor package 1C may further include a second bridge structure 505b electrically connecting the memory device 900 and the semiconductor chip 410. In an embodiment, the bridge structure 505 electrically connecting the semiconductor chip 410 and the optical engine device 100 shown in FIG. 6 may be referred to as a first bridge structure 505a.

According to an embodiment, the second bridge structure 505b may be disposed within the interposer substrate 501. The second bridge structure 505b may be disposed within the interposer substrate 501 and configured to electrically connect the semiconductor chip 410 and the memory device 900. According to an embodiment, the second bridge structure 505b may be a silicon (Si) bridge embedded within the interposer substrate 501. The second bridge structure 505b may be physically and electrically connected to the first chip bumps 415 connected to the semiconductor chip 410 and the third conductive bumps 930 of the memory device 900, within the interposer substrate 501. Therefore, the semiconductor chip 410 and the memory device 900 may transmit and/or receive electrical signals to and/or from each other through the second bridge structure 505b of the interposer 500.

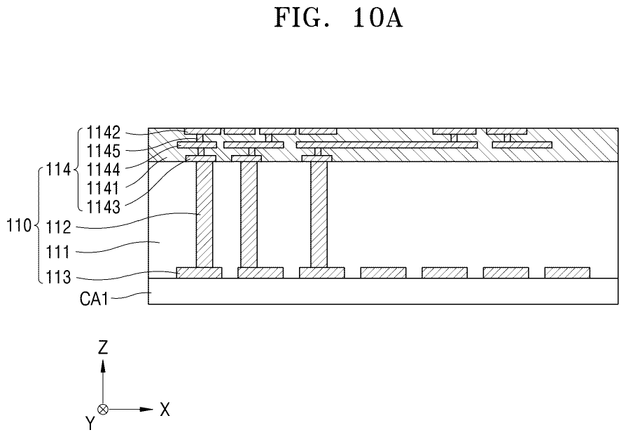

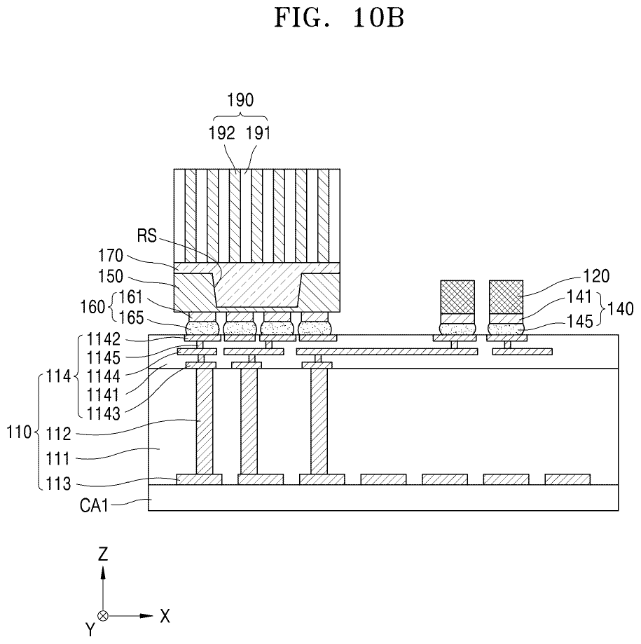

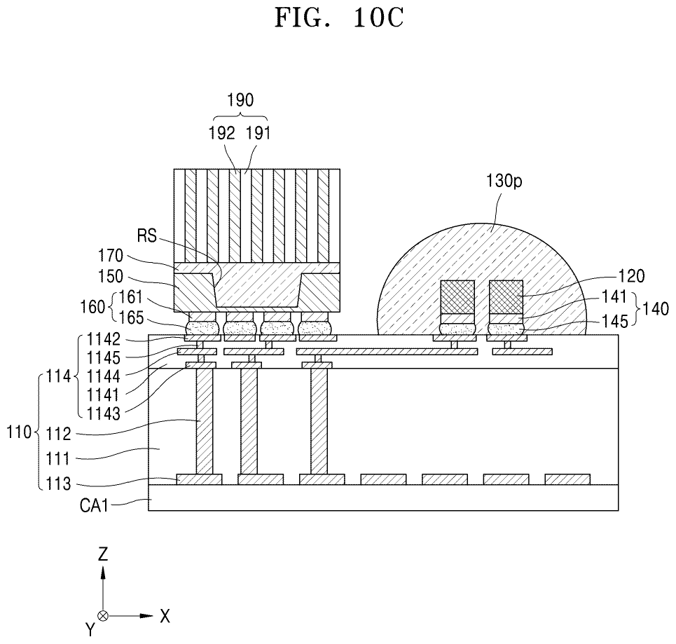

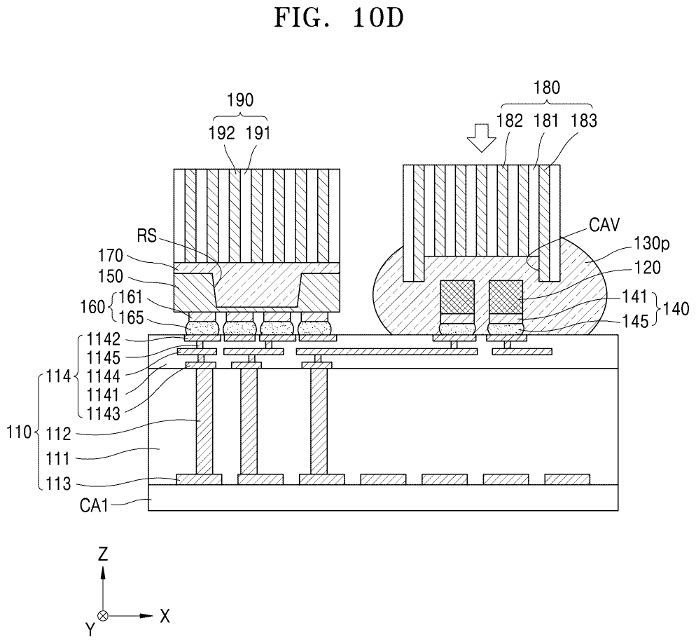

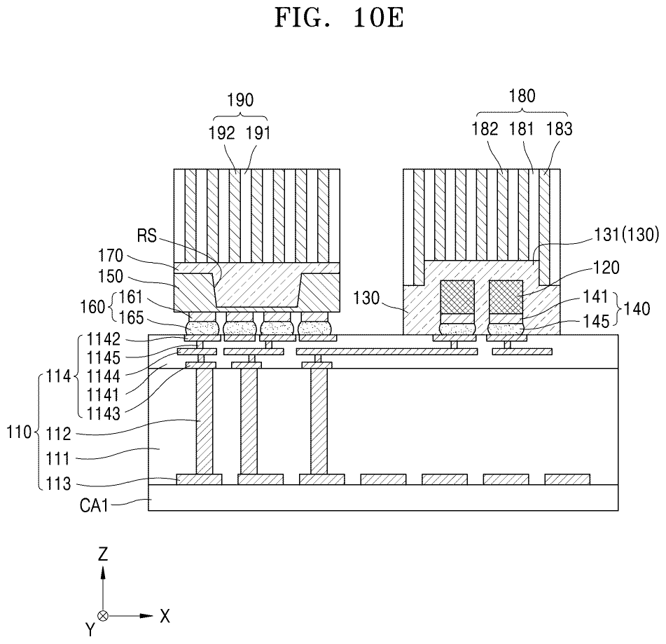

FIGS. 10A to 10E are cross-sectional views sequentially illustrating a process of manufacturing a semiconductor package, according to an embodiment.

Referring to FIG. 10A, a first cavity substrate CA1 may be prepared. The first cavity substrate CA1 may be and/or may include a wafer-level substrate. The first cavity substrate CA1 may include, but is not limited to, a silicon (Si) wafer.

The substrate 111 may be attached onto the first cavity substrate CA1. The plurality of conductive pads 113 may be arranged along the bottom surface of the substrate 111, and the through via 112 may extend from the bottom surface to the top surface through the substrate 111. The integrated circuit chip 110 may be attached such that the plurality of conductive pads 113 face the first cavity substrate CA1.

Thereafter, the wiring structure 114 may be formed on the top surface of the substrate 111. The wiring structure 114 may include the insulation layer 1141, the upper pad 1142, the lower pad 1143, the wiring pattern 1144, and the wiring via 1145. The insulation layer 1141 may be formed by depositing an insulation material on the top surface of the substrate 111. The insulation material may be formed through a deposition process such as, but not limited to, a physical vapor deposition (PVD) process or a chemical vapor deposition (CVD) process.

The upper pad 1142, the lower pad 1143, the wiring pattern 1144, and the wiring via 1145 may be formed by depositing insulation material, etching a portion of the insulation material, and then filling an etched portion with a conductive material. During formation of the process of forming the upper pad 1142, the lower pad 1143, the wiring pattern 1144, and the wiring via 1145, a barrier surrounding the upper pad 1142, the lower pad 1143, the wiring pattern 1144, and the wiring via 1145 may be formed to potentially prevent a conductive material from diffusing into the insulation layer 1141.

Referring to FIG. 10B, the photo detector 150 and the light-emitting device 120 may be mounted on the wiring structure 114. In an embodiment, the light-emitting device 120 may be mounted using a flip-chip bonding method via the first conductive bump 140, and the photo detector 150 may be mounted using a flip-chip bonding method via the second conductive bump 160.

The first conductive bump 140 may include the first pillar pattern 141 and the first solder pattern 145 attached to the bottom surface of the first pillar pattern 141. The second conductive bump 160 may include the second pillar pattern 161 and the second solder pattern 165 attached to the bottom surface of the second pillar pattern 161.

The first solder pattern 145 and the second solder pattern 165 may be attached to the upper pads 1142 of the wiring structure 114.

The photo detector 150 may include the recess RS recessed from the top surface toward the integrated circuit chip 110, and the second optical adhesive layer 170 may be formed to extend along the top surface of the photo detector 150 and fill the recess RS. Also, the second optical fiber plate 190 may be attached along the top surface of the second optical adhesive layer 170. According to an embodiment, no other material may be provided between the second optical adhesive layer 170 and the second optical fiber plate 190, and the second optical adhesive layer 170 and the second optical fiber plate 190 may be in direct contact with each other. However, the present disclosure is not limited in this regard. For example, according to some embodiments, other materials may be provided between the second optical adhesive layer 170 and the second optical fiber plate 190.

Referring to FIG. 10C, an optical adhesive material 130p sealing the light-emitting device 120 and the first conductive bump 140 may be formed on the wiring structure 114. In an embodiment, the optical adhesive material 130p may seal all of a plurality of light-emitting devices 120 pieces and a plurality of first conductive bumps 140. According to an embodiment, during formation of the optical adhesive material 130p, the optical adhesive material 130p may have a hemispherical shape with a convex surface.

According to an embodiment, the optical adhesive material 130p may include a material that may be cured by light and/or heat. The optical adhesive material 130p may include, but not be limited to, silicon (Si) or epoxy resin.

Referring to FIG. 10D, the first optical fiber plate 180 may be attached on the optical adhesive material 130p. According to an embodiment, the first optical fiber plate 180 may include the cavity CAV defined on the bottom surface of the first optical fiber plate 180. The cavity CAV may be formed in the vertical direction (Z direction). The first optical fiber plate 180 may include the inner optical fiber 182 that may overlap the cavity CAV in the vertical direction Z direction, the outer optical fiber 183 that may not overlap the cavity CAV, and the first protective layer 181 configured to seal the inner optical fiber 182 and the outer optical fiber 183.

Within the cavity CAV, the inner optical fiber 182 and the first protective layer 181 may be partially exposed. Also, according to some embodiments, the sidewall within the cavity CAV may include some of outer optical fibers 183. The cavity CAV of the first optical fiber plate 180 may be filled with the optical adhesive material 130p. The optical engine device 100 and the first optical fiber plate 180 may be spaced apart from each other in the vertical direction (Z direction). In an embodiment, in a plan view, the optical engine device 100 may overlap the cavity CAV of the first optical fiber plate 180 in the vertical direction (Z direction).

Referring to FIG. 10E, thereafter, the sidewalls of the optical adhesive material 130p may be etched. Etched sidewalls of the optical adhesive material 130p may be coplanar with the sidewalls of the first optical fiber plate 180. The first optical adhesive layer 130 may be completed when the sidewalls of the optical adhesive material 130p are etched. Also, a portion of the first optical adhesive layer 130 that fills the cavity CAV of the first optical fiber plate 180 may be defined as the protrusion 131.

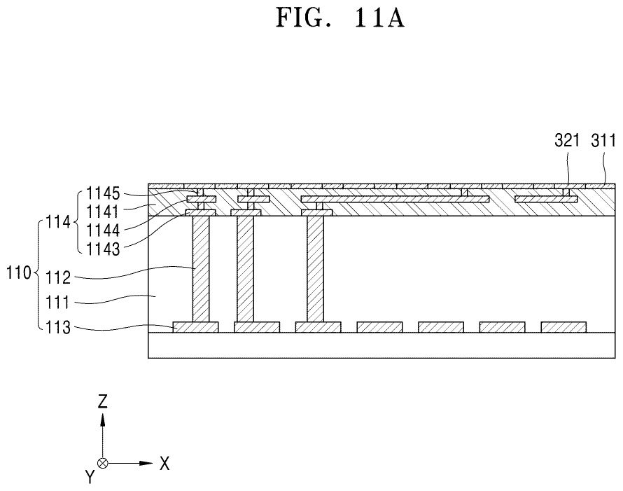

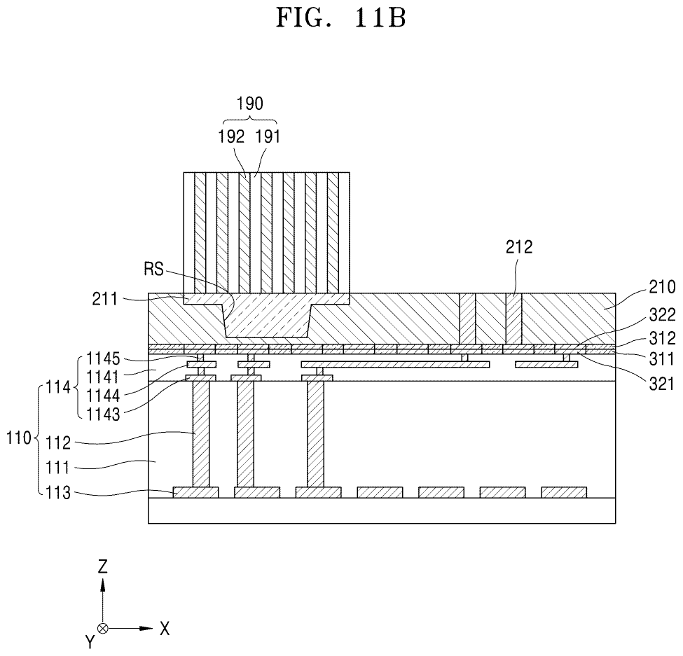

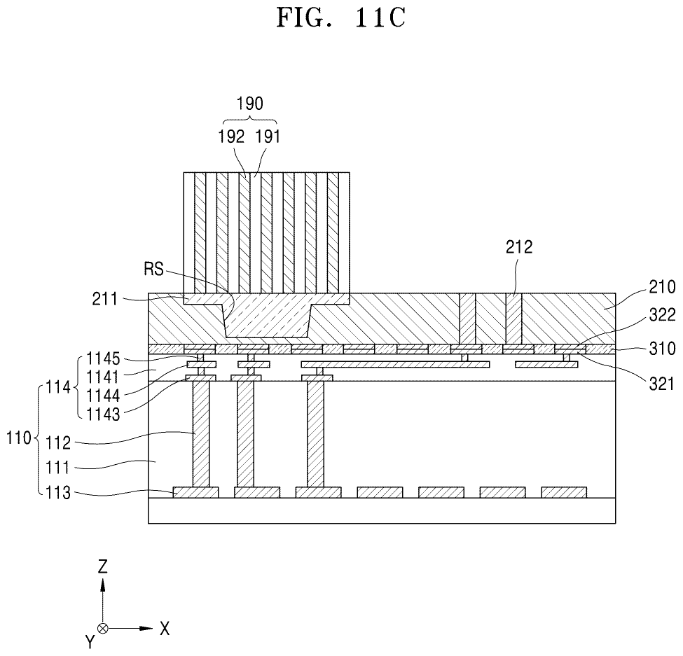

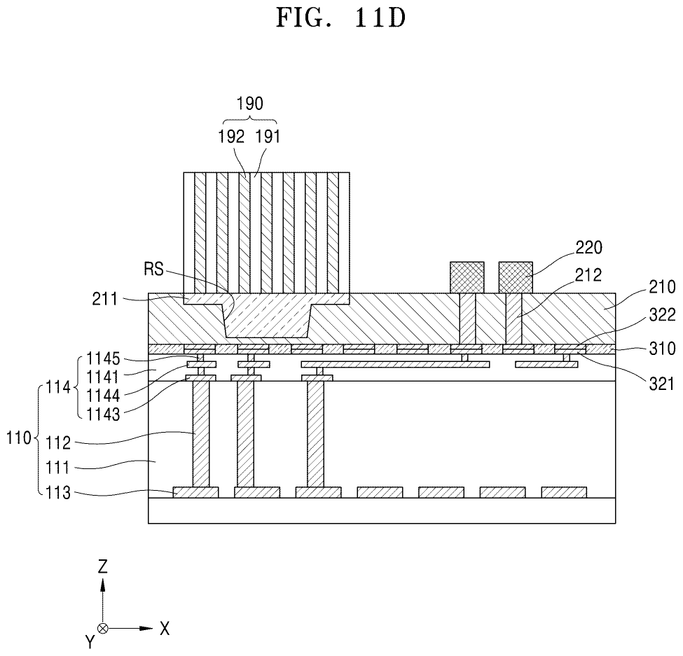

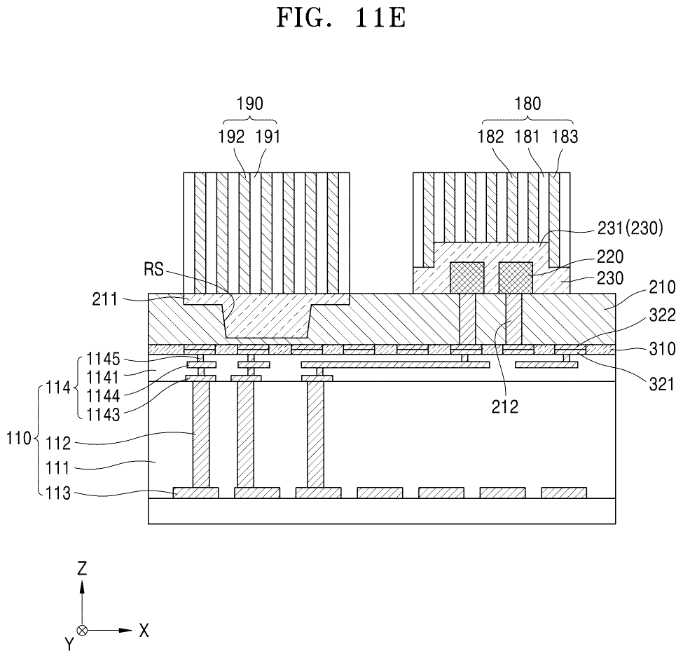

FIGS. 11A to 11E are cross-sectional views sequentially illustrating a process of manufacturing the semiconductor package 1, according to an embodiment.

The process of manufacturing the semiconductor package 1 shown in FIGS. 11A to 11E represents the process of manufacturing the semiconductor package 1 shown in FIG. 4.

Referring to FIG. 11A, a lower chip bonding insulation layer 311 and the lower chip bonding pad 321 may be formed on the integrated circuit chip 110 on which the wiring structure 114 is formed. The lower chip bonding insulation layer 311 may be formed through a deposition process, and the lower chip bonding pad 321 may be formed through a plating process. A plurality of lower chip bonding pads 321 may be provided on the top surface of the insulation layer 1141 of the wiring structure 114. At least some of the plurality of lower chip bonding pads 321 may be positioned to contact wiring vias 1145.

According to an embodiment, the bottom surface of the lower chip bonding insulation layer 311 may be coplanar with the bottom surface of the lower chip bonding pad 321, and the top surface of the lower chip bonding insulation layer 311 may be coplanar with the top surface of the lower chip bonding pad 321. Also, the side surfaces of the lower chip bonding insulation layer 311 may be coplanar with the side surfaces of the insulation layer 1141 and the side surfaces of the substrate 111.

Referring to FIG. 11B, the photo detector 210 including an upper chip bonding insulation layer 312 and the upper chip bonding pad 322 on the bottom surface of the photo detector 210 may be attached on the wiring structure 114.

A plurality of lower chip bonding pads 321 may be provided on the lower chip bonding insulation layer 311. A plurality of upper chip bonding pads 322 may be arranged to contact the lower chip bonding pads 321, respectively. Although FIG. 11B illustrates that the upper chip bonding pad 322 is positioned to be completely aligned with the lower chip bonding pad 321 in the vertical direction (Z direction), according to some embodiments, the side surfaces of the upper chip bonding pad 322 and the side surfaces of the lower chip bonding pad 321 may be positioned to be misaligned with each other.

According to an embodiment, the bottom surface of the upper chip bonding insulation layer 312 may be coplanar with the bottom surface of the upper chip bonding pad 322, and the top surface of the upper chip bonding insulation layer 312 may be coplanar with the top surface of the upper chip bonding pad 322. Also, the side surfaces of the upper chip bonding insulation layer 312 may be coplanar with the side surfaces of the insulation layer 1141 and the side surfaces of the substrate 111.

The photo detector 210 may be positioned on the upper chip bonding insulation layer 312. According to an embodiment, instead of the photo detector 210 being directly attached to the upper chip bonding insulation layer 312, a substrate on which the photo detector 210 is provided may be attached to the upper chip bonding insulation layer 312.

The second through via 212 penetrating through the photo detector 210 may be formed within the photo detector 210. The second through via 212 may be connected to the upper chip bonding pad 322. The bottom surface of the second through via 212 may be connected to the top surface of the upper chip bonding pad 322. In an embodiment, the top surface of the through via 112 may be exposed on the top surface of the photo detector 210.

According to an embodiment, the photo detector 250 may include the recess RS recessed from the top surface of the photo detector 150 toward the integrated circuit chip 110. Also, the second optical adhesive layer 211 may be provided on the second optical fiber plate 190 and the photo detector 210. The second optical adhesive layer 211 may extend along the top surface of the photo detector 210 to fill the recess RS. The recess RS may be formed by etching the photo detector 210.

Thereafter, the second optical fiber plate 190 may be attached to be aligned with the second optical adhesive layer 211 of the photo detector 210.

Referring to FIG. 11C, the lower chip bonding pad 321 and the upper chip bonding pad 322 may be bonded through a hybrid bonding process. In the process of bonding the photo detector 210 to the wiring structure 114, heat and/or pressure may be applied to bond the lower chip bonding pad 321 and the upper chip bonding pad 322 and/or to bond the lower chip bonding insulation layer 311 and the upper chip bonding insulation layer 312. According to some embodiments, the lower chip bonding pad 321 and the upper chip bonding pad 322 and the lower chip bonding insulation layer 311 and the upper chip bonding insulation layer 312 may be bonded to form a covalent bond. For example, in the process of positioning the photo detector 210 on the integrated circuit chip 110, heat of a first temperature may be applied.

Thereafter, heat of a second temperature that may be higher (hotter) than the first temperature may be applied to bond the lower chip bonding pad 321 and the upper chip bonding pad 322 corresponding to each other and form the chip bonding insulation layer 310 in which the lower chip bonding insulation layer 311 and the upper chip bonding insulation layer 312 are bonded to each other. The lower chip bonding pad 321 and the upper chip bonding pad 322 corresponding to each other may expand by heat to come into contact with each other and may then be diffusion bonded to form an integral body through diffusion of metal atoms therein.

Referring to FIG. 11D, the light-emitting device 220 may be mounted on the top surface of the photo detector 210. In an embodiment, a plurality of light-emitting devices 220 may be provided, and the plurality of light-emitting devices 220 may be aligned in a vertical direction (Z direction) with respect to the second through vias 212. That is, the plurality of light-emitting devices 220 may be connected to the second through via 212 to overlap the second through vias 212 in the vertical direction (Z direction). The plurality of light-emitting devices 220 may be electrically connected to the second through vias 212.

Referring to FIG. 11E, the first optical adhesive layer 230 may be formed on the top surface of the photo detector 210, and the first optical fiber plate 180 may be positioned on the first optical adhesive layer 230. The first optical adhesive layer 230 may be substantially similar to and/or the same as the first optical adhesive layer 230 formed through the process shown in FIGS. 10C to 10E. However, the first optical adhesive layer 230 of FIG. 11E may be formed on the top surface of the photo detector 210 rather than on the insulation layer 1141 of the wiring structure 114. Consequently, repeated descriptions of the formation of the first optical adhesive layer 230 described in with reference to FIGS. 10C to 10E may be omitted below for the sake of brevity.

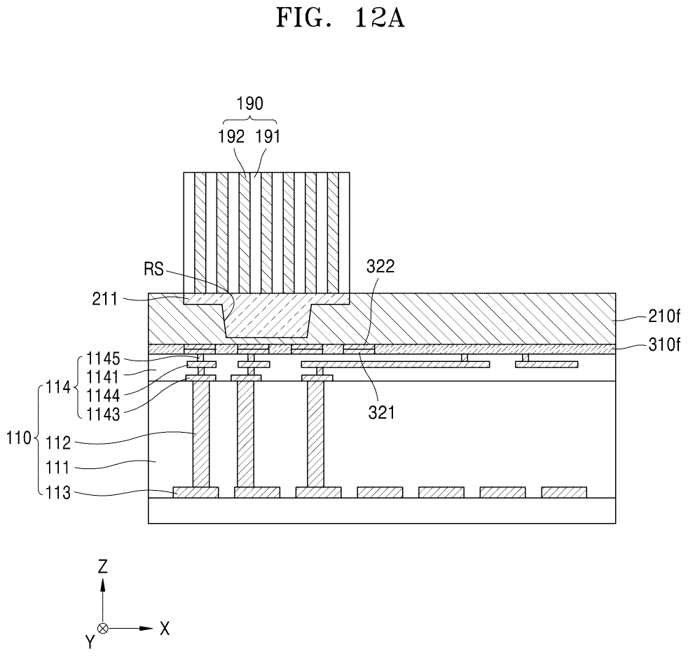

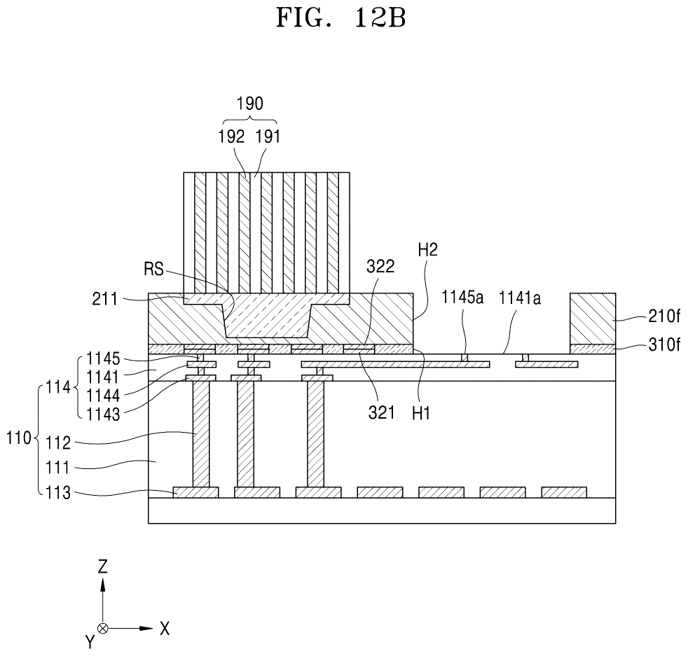

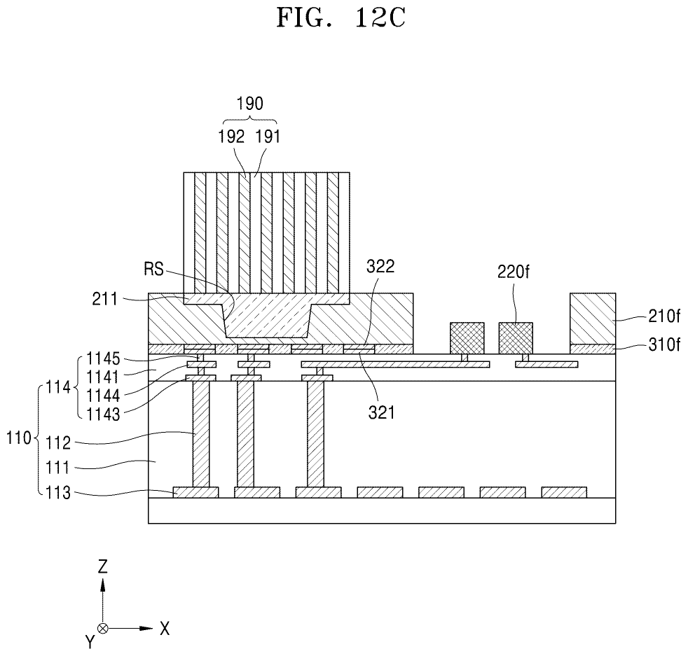

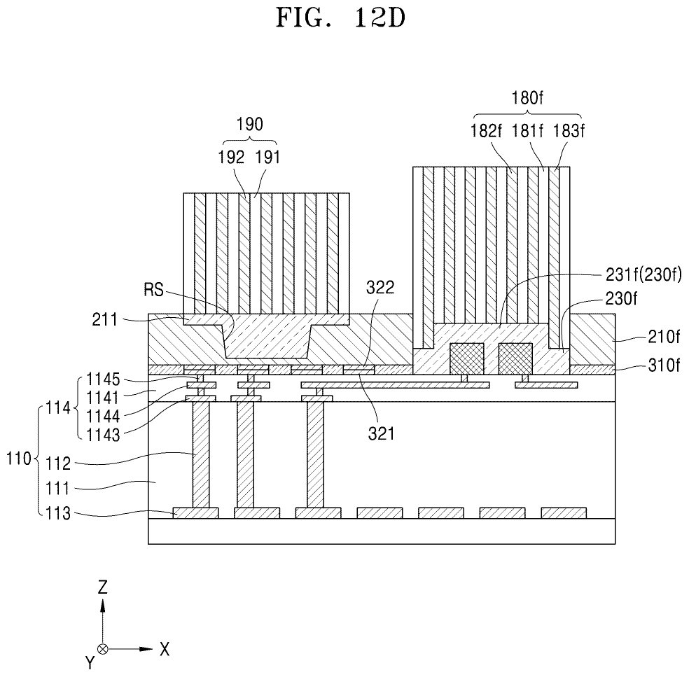

FIGS. 12A to 12D are cross-sectional views sequentially illustrating a process of manufacturing a semiconductor package, according to an embodiment.

The process of manufacturing a semiconductor package shown in FIGS. 12A to 12D represents the process of manufacturing the optical engine device 10F shown in FIG. 5.

Referring to FIG. 12A, the integrated circuit chip 110 may be disposed on the first cavity substrate CA1, and the photo detector 210f hybrid-bonded with the integrated circuit chip 110 may be provided. The incomplete semiconductor package shown in FIG. 12A may be substantially similar to and/or the same as the incomplete semiconductor package shown in FIG. 11C. However, the incomplete semiconductor package shown in FIG. 12A may not include the second through via 212 penetrating through the photo detector 210f. Consequently, repeated descriptions thereof may be omitted below for the sake of brevity.

Referring to FIG. 12B, the photo detector 210f and the chip bonding insulation layer 310 may be etched to form the first hole H1 penetrating through the chip bonding insulation layer 310 and the second hole H2 penetrating through the photo detector 210f. In an embodiment, the first hole H1 penetrating through the chip bonding insulation layer 310 and the second hole H2 penetrating through the photo detector 210f may be aligned to each other in the vertical direction (Z direction). That is, the sidewall within the first hole H1 and the sidewall within the second hole H2 may be coplanar with each other.

Also, a portion of the insulation layer 1141 of the wiring structure 114 and some of the plurality of wiring vias 1145 may be exposed within the first hole H1.

Referring to FIG. 12C, the light-emitting device 220f may be disposed on the wiring via 1145 within the first hole H1 of the chip bonding insulation layer 310 and the second hole H2 of the photo detector 210f. The light-emitting device 220f may be aligned to be electrically connected to the wiring via 1145 within the first hole H1 and the second hole H2.

Referring to FIG. 12D, the first optical adhesive layer 230f may be formed on the top surface of the insulation layer 1141 of the wiring structure 114, and the first optical fiber plate 180f may be positioned on the first optical adhesive layer 230f. The first optical adhesive layer 230f may be substantially similar to and/or the same as the first optical adhesive layer 230f formed through the process shown in FIGS. 10C to 10E. However, the first optical adhesive layer 230f shown in FIG. 12D may be formed within the first hole H1 of the chip bonding insulation layer 310 and the second hole H2 of the photo detector 210f. Consequently, repeated descriptions of the formation of the first optical adhesive layer 230f described with reference to FIGS. 10C to 10E may be omitted below for the sake of brevity.

The first optical fiber plate 180f may include the inner optical fiber 182f, the outer optical fiber 183f, and a first protective layer 181f. In an embodiment, the inner optical fiber 182f may be and/or may include an optical fiber that may overlap the protrusion 231f of the first optical adhesive layer 230f, and the outer optical fiber 183f may be and/or may include an optical fiber that may not overlap the protrusion 231f of the first optical adhesive layer 230f. The sidewalls of the first optical fiber plate 180f may be in contact with the inner walls of the photo detector 210f within the first hole H1 of the photo detector 210f.

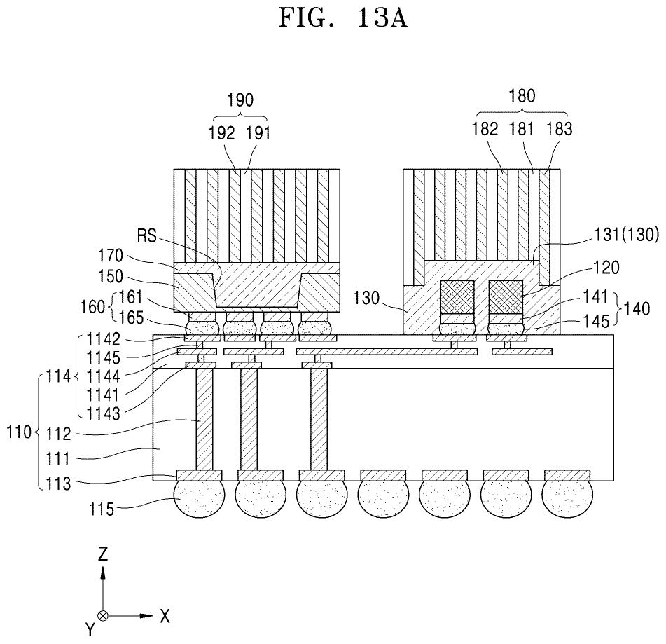

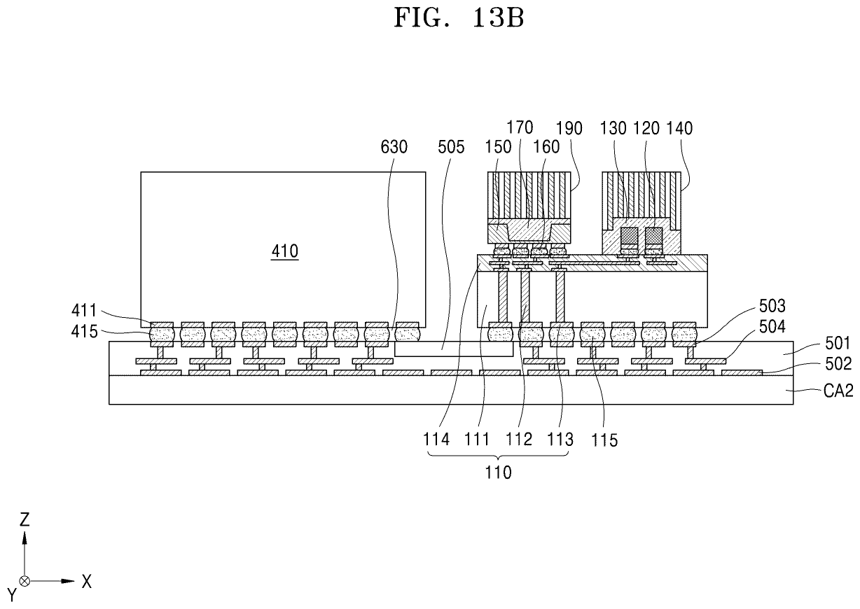

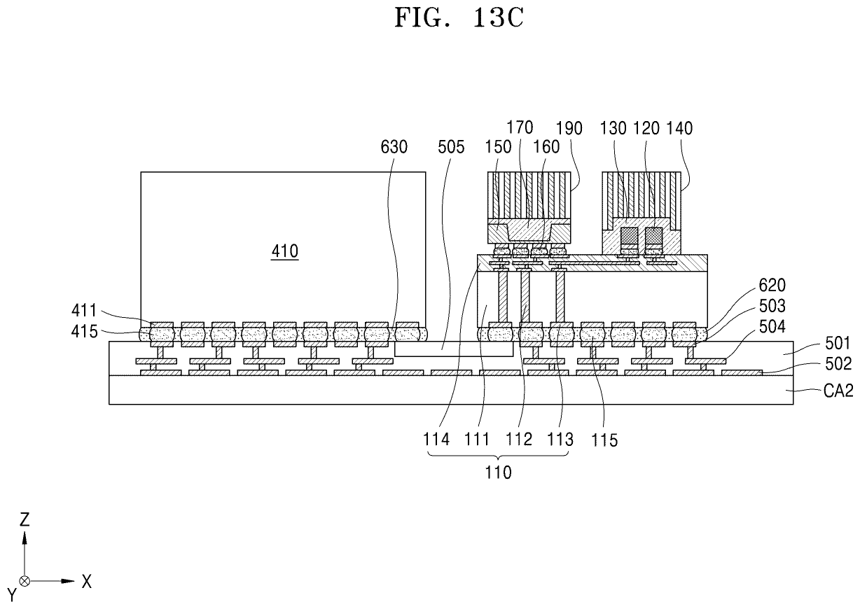

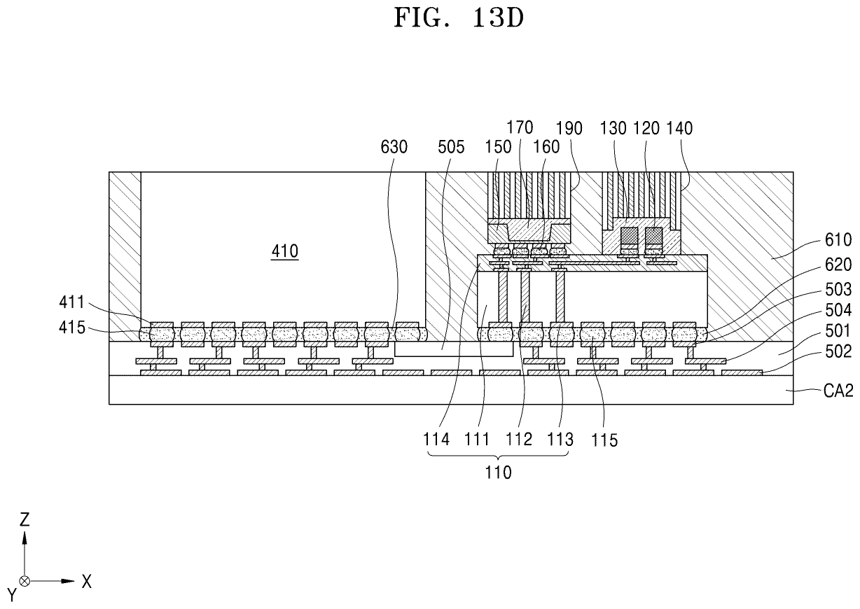

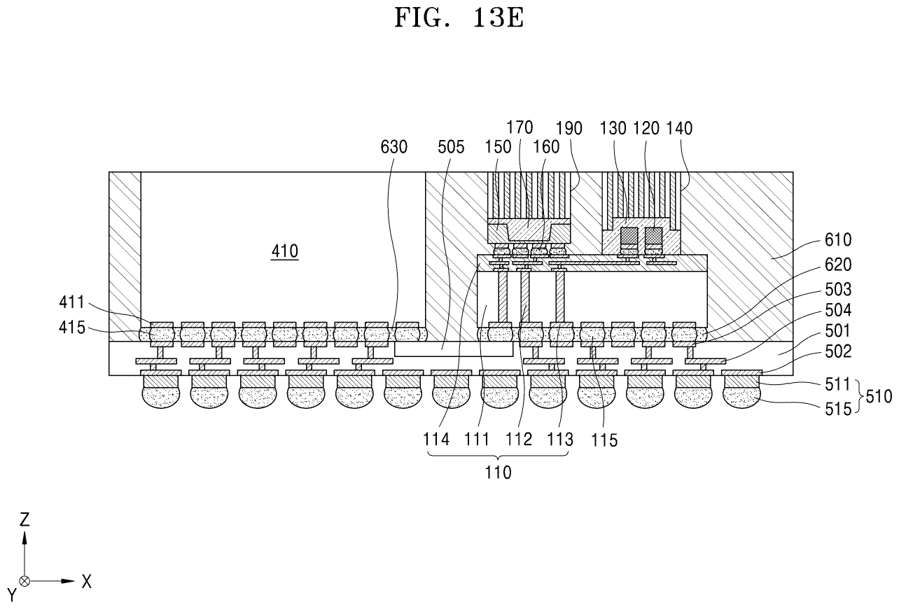

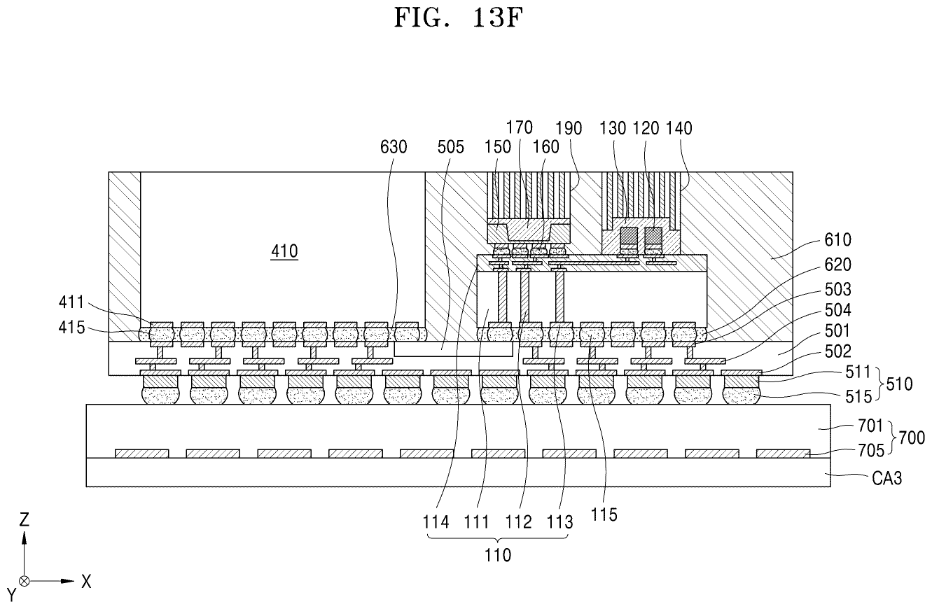

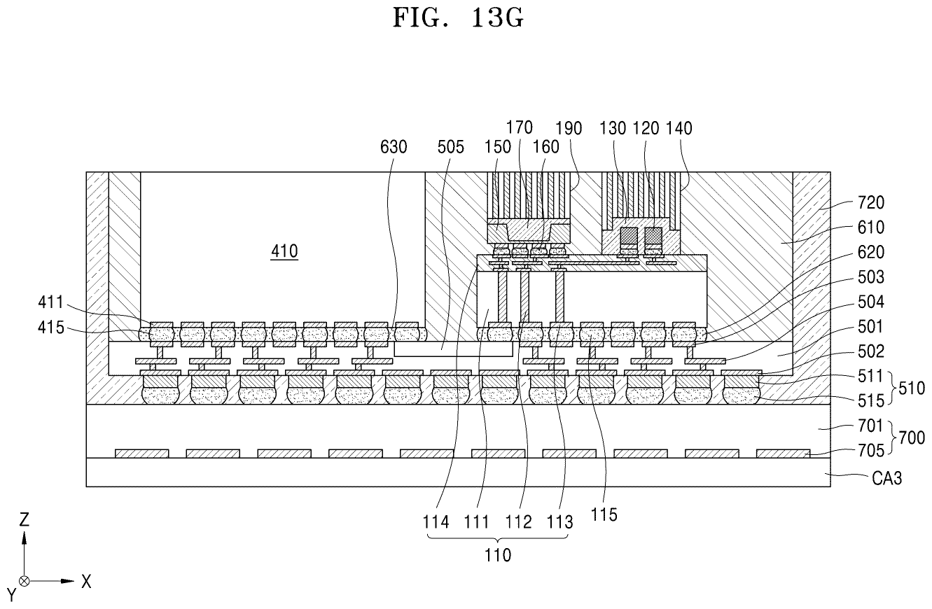

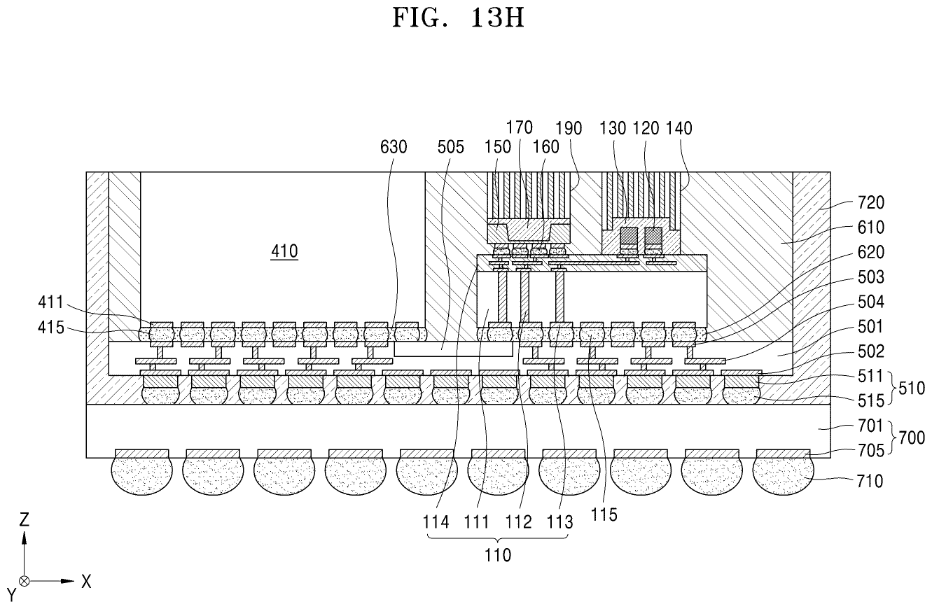

FIGS. 13A to 13G are cross-sectional views sequentially illustrating a process of manufacturing a semiconductor package, according to an embodiment.

FIG. 13A is a process of manufacturing a semiconductor package that may continue from FIG. 10E. Referring to FIG. 13A, after removing the first cavity substrate CA1, the connection terminals 115 may be formed on the lower pads 1143 arranged along the bottom surface of the substrate 111.

Referring to FIG. 13B, the interposer substrate 501 may be provided on a second cavity substrate CA2. In an embodiment, a plurality of lower substrate pads 502 may be arranged to be spaced apart from each other in the lateral direction (X direction and/or Y direction) on the bottom surface of the interposer substrate 501, and a plurality of upper substrate pads 503 may be arranged to be spaced apart from each other in the lateral direction (X direction and/or Y direction) on the top surface of the interposer substrate 501.

Also, a plurality of substrate wires 504 extending in the lateral direction (X direction and/or Y direction) may be arranged inside the interposer substrate 501. Although FIG. 13B shows that the plurality of substrate wires 504 are at the same vertical level, the present disclosure is not limited in this regard. For example, according to some embodiments, the plurality of substrate wires 504 may be arranged at different vertical levels.

Also, vias may be formed to electrically connect between the plurality of substrate wires 504 at different vertical levels, between the substrate wires 504 located at the topmost substrate wires 504 and the upper substrate pads 503, or between the bottommost substrate wires 504 and the lower substrate pads 502.

Also, the bridge structure 505 may be formed inside the interposer substrate 501. The bridge structure 505 may be configured to physically and electrically connect the semiconductor chip 410 and the optical engine device 100.

The semiconductor chip 410 and the optical engine device 100 may be mounted on the top surface of the interposer substrate 501. In an embodiment, the first chip bump 415 attached to the semiconductor chip 410 and the connection terminal 115 of the integrated circuit chip 110 may be attached to the upper substrate pad 503 exposed on the top surface of the interposer substrate 501.

Referring to FIG. 13C, the first underfill film 620 may be formed to cover the sidewalls of the connection terminals 115 located between the interposer substrate 501 and the substrate 111 of the integrated circuit chip 110. Also, the second underfill film 630 may be formed to cover the sidewalls of the first chip bumps 415 located between the interposer substrate 501 and the semiconductor chip 410. The first underfill film 620 and the second underfill film 630 may be formed by using a capillary underfill method. The first underfill film 620 and the second underfill film 630 may include, for example, epoxy resin.

According to an embodiment, the first underfill film 620 and the second underfill film 630 may include mixed fillers. The fillers may include, but not be limited to silica. The fillers may have a size, for example, from about 0.1 micrometers (μm) to several μm, and may have an average size from about 0.3 to about 1 μm. The first underfill film 620 and the second underfill film 630 may be mixed with fillers having a mass, for example, from about 55% to about 75%. That is, the ratio of filler included in the first underfill film 620 and the second underfill film 630 may be from about 55 wt % to about 75 wt %.

Referring to FIG. 13D, the first molding layer 610 may be disposed on the interposer 500 to cover the sidewalls of the semiconductor chip 410 and the sidewalls of the optical engine device 100. A grinding process may be further performed on the first molding layer 610, and thus the top surface of the semiconductor chip 410, the top surface of the first optical fiber plate 180, and the top surface of the second optical fiber plate 190 may be exposed on the top surface of the first molding layer 610.

Referring to FIG. 13E, after removing the second cavity substrate CA2, the interposer bumps 510 may be formed on the bottom surface of the interposer 500. The interposer bumps 510 may include the interposer pillar pattern 511 and the interposer solder pattern 515. A plurality of interposer bumps 510 may be provided, and the top surfaces of the plurality of interposer pillar patterns 511 may be attached to the bottom surfaces of the lower substrate pads 502 arranged along the bottom surface of the interposer 500, respectively. The interposer solder pattern 515 may be attached to the bottom surface of the interposer pillar pattern 511.

Referring to FIG. 13F, the package substrate 700 including the base substrate 701 and the metal pads 705 may be provided. The package substrate 700 may be provided on a third cavity substrate CA3. Thereafter, the interposer 500 may be mounted on the package substrate 700. The interposer solder pattern 515 of the interposer bump 510 may be electrically connected to the package substrate 700.

Referring to FIG. 13G, the second molding layer 720 may be disposed on the package substrate 700 to cover the sidewalls of the first molding layer 610 and the sidewalls of the interposer bumps 510. A grinding process may be further performed on the second molding layer 720, and thus the top surface of the semiconductor chip 410, the top surface of the first optical fiber plate 180, and the top surface of the second optical fiber plate 190 may be exposed on the top surface of the second molding layer 720.

Referring to FIG. 13H, subsequent to removing the third cavity substrate CA3, the external connection terminal 710 may be formed on the bottom surface of the package substrate 700. A plurality of external connection terminals 710 may be provided, and the top surfaces of the plurality of external connection terminals 710 may be attached to the bottom surfaces of the metal pads 705 arranged along the bottom surface of the package substrate 700, respectively. When the plurality of external connection terminals 710 are attached to the metal pads 705, the semiconductor package 1, according to an embodiment, may be completed.

While the present disclosure has been particularly shown and described with reference to embodiments thereof, it is to be understood that various changes in form and details may be made therein without departing from the spirit and scope of the following claims.

What is claimed is:

1. An optical engine device, comprising:
an integrated circuit chip having a top surface orthogonal to a vertical direction;
a light-emitting device on the top surface of the integrated circuit chip and coupled with the integrated circuit chip;
a first optical adhesive layer comprising a protrusion and configured to seal the light-emitting device; and
an optical fiber plate comprising a cavity facing the first optical adhesive layer,
wherein the protrusion of the first optical adhesive layer is coupled with the optical fiber plate within the cavity.

2. The optical engine device of claim 1, wherein the light-emitting device at least partially overlaps the protrusion of the first optical adhesive layer in the vertical direction.

3. The optical engine device of claim 1, further comprising:
a first conductive bump coupled with the light-emitting device,
wherein the light-emitting device is flip-chip bonded to the integrated circuit chip via the first conductive bump.

4. The optical engine device of claim 1, further comprising:
a photo detector on the integrated circuit chip and laterally spaced apart from the light-emitting device; and
a second conductive bump coupled with the photo detector,
wherein the photo detector is flip-chip bonded to the integrated circuit chip via the second conductive bump.

5. The optical engine device of claim 4, wherein the photo detector comprises a recess recessed from a top surface of the photo detector toward the integrated circuit chip, and
wherein the optical engine device further comprises a second optical adhesive layer extending along the top surface of the photo detector and at least partially filling the recess.

6. The optical engine device of claim 4, wherein the integrated circuit chip comprises a plurality of through vias extending in the vertical direction, and
wherein the plurality of through vias at least partially overlap at least one of the photo detector or the light-emitting device, in the vertical direction.

7. The optical engine device of claim 1, wherein the optical fiber plate further comprises:
a sidewall within the cavity of the optical fiber plate and inclined with respect to the vertical direction.

8. The optical engine device of claim 1, wherein the optical fiber plate further comprises a plurality of cavities,
wherein the plurality of cavities are laterally spaced apart from each other, and
wherein each cavity of the plurality of cavities at least partially overlaps the light-emitting device in the vertical direction.

9. The optical engine device of claim 1, wherein the optical fiber plate further comprises a plurality of cavities,
wherein the plurality of cavities comprise a first cavity and a second cavity within the first cavity,
wherein a width of the second cavity is smaller than a width of the first cavity,
wherein the first cavity overlaps the light-emitting device, and
wherein the second cavity at least partially overlaps at least a portion of the light-emitting device.

10. The optical engine device of claim 1, wherein the optical fiber plate further comprises:
a plurality of optical fibers extending in the vertical direction; and
a protective layer at least partially covering the plurality of optical fibers,
wherein one or more optical fibers of the plurality of optical fibers are exposed within the cavity.

11. The optical engine device of claim 1, further comprising:
a universal chiplet interconnect express (UCIE) chip on the integrated circuit chip and coupled with the light-emitting device.

12. An optical engine device, comprising:
an integrated circuit chip comprising a first through via extending in a vertical direction;
a photonics chip on the integrated circuit chip;
a pair of chip bonding pads directly bonded to each other and disposed between the integrated circuit chip and the photonics chip; and
a chip bonding insulation layer at least partially surrounding the pair of chip bonding pads and disposed between the integrated circuit chip and the photonics chip,
wherein the photonics chip comprises:
a light-emitting device on the chip bonding insulation layer and coupled with the integrated circuit chip;
a photo detector on the chip bonding insulation layer and laterally spaced apart from the light-emitting device;
a wiring structure between the first through via and each of the pair of chip bonding pads;
an optical adhesive layer comprising a protrusion and configured to seal the light-emitting device; and
an optical fiber plate comprising a cavity facing the optical adhesive layer, and
wherein the cavity of the optical fiber plate is at least partially filled by the protrusion of the optical adhesive layer.

13. The optical engine device of claim 12, wherein the wiring structure is coupled with the light-emitting device and the photo detector.

14. The optical engine device of claim 12, wherein the photonics chip further comprises a second through via at least partially penetrating through the photo detector, and
wherein the second through via couples the light-emitting device with the pair of chip bonding pads.

15. The optical engine device of claim 12, wherein the chip bonding insulation layer comprises a first plurality of holes,
wherein the photo detector comprises a second plurality of holes,
wherein the first plurality of holes are respectively aligned with the second plurality of holes in the vertical direction, and
wherein the light-emitting device is disposed within the first plurality of holes and the second plurality of holes.

16. The optical engine device of claim 12, wherein the wiring structure comprises a plurality of wiring patterns extending laterally and coupled with the light-emitting device, and
wherein the first through via does not overlap the light-emitting device in the vertical direction.

17. The optical engine device of claim 12, wherein the optical adhesive layer is in direct contact with the optical fiber plate.

18. A semiconductor package, comprising:
an interposer comprising an interposer substrate;
a non-memory device on the interposer substrate;
an optical engine device on the interposer substrate and laterally spaced apart from the non-memory device; and
a sealing layer on the interposer substrate and configured to seal the non-memory device and the optical engine device,
wherein the optical engine device comprises:
an integrated circuit chip comprising a through via extending in a vertical direction;
a wiring structure on the integrated circuit chip and coupled with the integrated circuit chip;
a light-emitting device on the wiring structure and coupled with the wiring structure;
a photo detector on the wiring structure and laterally spaced apart from the light-emitting device;
an optical adhesive layer comprising a protrusion and configured to seal the light-emitting device; and
an optical fiber plate comprising a cavity facing the optical adhesive layer and at least partially surrounding the protrusion.

19. The semiconductor package of claim 18, wherein the optical engine device further comprises:
a first conductive bump coupled with the light-emitting device; and
a second conductive bump coupled with the photo detector,
wherein the light-emitting device is flip-chip bonded to the wiring structure via the first conductive bump, and
wherein the photo detector is flip-chip bonded to the wiring structure via the second conductive bump.

20. The semiconductor package of claim 18, wherein the interposer further comprises:
a bridge structure coupling the optical engine device with the non-memory device within the interposer substrate.
